(19) United States
(12) Patent Application Publication
(10) Pub. No.: US 2026/0020335 A1
(43) Pub. Date: Jan. 15, 2026

(54) SEMICONDUCTOR DEVICE AND METHOD OF FABRICATING THE SAME

(71) Applicant: Samsung Electronics Co., Ltd., Suwon-si (KR)

(72) Inventors: Byunghee Son, Suwon-si (KR); Jaeyeop Lee, Suwon-si (KR); Yu Jin Jeon, Suwon-si (KR); Seung Geun Jung, Suwon-si (KR)

(21) Appl. No.: 19/053,145

(22) Filed: Feb. 13, 2025

(30) Foreign Application Priority Data
Jul. 9, 2024 (KR) 10-2024-0090042

(51) Int. Cl. H10D 84/85; H10D 30/00; H10D 30/01; H10D 30/43; H10D 62/10; H10D 62/13; H10D 64/23; H10D 84/01

(52) U.S. Cl. CPC H10D 84/851; H10D 30/014; H10D 30/0194; H10D 30/43; H10D 30/503; H10D 30/506; H10D 62/102; H10D 62/121; H10D 62/151; H10D 64/256; H10D 84/0167; H10D 84/0186

(57) ABSTRACT

A semiconductor device may include a channel pattern on a substrate, a source/drain pattern electrically connected to the channel pattern, a gate electrode on the channel pattern, an interlayer insulating layer on the source/drain pattern, and an active contact that extends into the interlayer insulating layer and is electrically connected to the source/drain pattern. The active contact may include a lower active contact, which includes a barrier pattern and a lower metal pattern on the barrier pattern, and an upper active contact on the lower active contact. The upper active contact may include an upper metal pattern and an insulating pattern on side surfaces of the upper metal pattern. The lower metal pattern and the upper metal pattern may be in contact with each other.

### CROSS-REFERENCE TO RELATED APPLICATIONS

This U.S. non-provisional patent application claims priority under 35 U.S.C. § 119 to Korean Patent Application No. 10-2024-0090042, filed on Jul. 9, 2024, in the Korean Intellectual Property Office, the entire contents of which are hereby incorporated by reference.

### TECHNICAL FIELD

The present disclosure relates to a semiconductor device, and in particular, to a semiconductor device including a field effect transistor.

### BACKGROUND

A semiconductor device includes an integrated circuit that includes metal-oxide-semiconductor field-effect transistors (MOSFETs). To meet an increasing demand for the semiconductor device with a small pattern size and a reduced design rule, the MOSFETs are being scaled down. The scale-down of the MOSFETs may lead to a deterioration in operation characteristics of the semiconductor device. Accordingly, a variety of studies are being conducted to overcome technical limitations associated with the scale-down of the semiconductor device and to provide high performance semiconductor device.

### SUMMARY

Some embodiments of the present disclosure provide a semiconductor device with improved electrical and reliability characteristics.

Some embodiments of the present disclosure provide a method of fabricating a semiconductor device with improved electrical and reliability characteristics.

According to some embodiments of the present disclosure, a semiconductor device may include a channel pattern on a substrate, a source/drain pattern electrically connected to the channel pattern, a gate electrode on the channel pattern, an interlayer insulating layer on the source/drain pattern, and an active contact that extends into the interlayer insulating layer and is electrically connected to the source/drain pattern. The active contact may include a lower active contact, which includes a barrier pattern and a lower metal pattern on the barrier pattern, and an upper active contact on the lower active contact. The upper active contact may include an upper metal pattern and an insulating pattern on side surfaces of the upper metal pattern. The lower metal pattern and the upper metal pattern may be in contact with each other.

According to some embodiments of the present disclosure, a semiconductor device may include a substrate including a first active region and a second active region, a first channel pattern on the first active region and a second channel pattern on the second active region, a first source/drain pattern electrically connected to the first channel pattern, a second source/drain pattern electrically connected to the second channel pattern, a gate electrode on the first channel pattern and the second channel pattern, a first active contact that extends into a portion of the first source/drain pattern, and a second active contact that extends into a portion of the second source/drain pattern. The first active contact may be configured to exert a tensile stress on the first channel pattern, and the second active contact may be configured to exert a compressive stress on the second channel pattern.

According to some embodiments of the present disclosure, a method of fabricating a semiconductor device may include providing a substrate including a first active region and a second active region, forming a first channel pattern and a first source/drain pattern that are electrically connected to each other and are on the first active region, forming a second channel pattern and a second source/drain pattern that are electrically connected to each other and are on the second active region, forming a first seed layer in a first contact recess that extends into a portion of the first source/drain pattern, and forming a second seed layer in a second contact recess that extends into a portion of the second source/drain pattern. The first and second seed layers may be configured to exert a stress on the first channel pattern and the second channel pattern, respectively.

### BRIEF DESCR1PT1ON OF THE DRAWINGS

FIGS. 1 to 3 are conceptual diagrams illustrating logic cells of a semiconductor device according to some embodiments of the present disclosure.

FIG. 4 is a plan view illustrating a semiconductor device according to some embodiments of the present disclosure.

FIGS. 5A, 5B, 5C, and 5D are sectional views taken along lines A-A′, B-B′, C-C′, and D-D′ of FIG. 4.

FIG. 6A is an enlarged sectional view illustrating a portion ‘P1’ of FIG. 5A.

FIG. 6B is an enlarged sectional view illustrating a portion ‘P2’ of FIG. 5B.

FIG. 7A is an enlarged sectional view illustrating the portion ‘P1’ of FIG. 5A.

FIG. 7B is an enlarged sectional view illustrating the portion ‘P2’ of FIG. 5B.

FIGS. 8A, 8B, 9A, 9B, 10A, 10B, 10C, 11A, 11B, 11C, 11D, 12A, 12B, 12C, 12D, 13A, 13B, 13C, 14A, 14B, 14C, 15A, 15B, 16A, and 16B are sectional views illustrating a method of fabricating a semiconductor device, according to some embodiments of the present disclosure.

### DETAILED DESCR1PT1ON

Example embodiments of the present disclosure will now be described more fully with reference to the accompanying drawings, in which example embodiments are shown. Like reference numerals in the drawings denote like elements, and thus their description will be omitted.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for case of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection

As used herein, “an element A being at a lower level than element B” refers to a distance between element A and a reference element in a given direction being less than a distance between element B and the reference element in the given direction. As used herein, “an element A being at a higher level than element B” refers to a distance between element A and a reference element in a given direction being greater than a distance between element B and the reference element in the given direction. As used herein, “an element A being at a same level as element B” refers to element A and element B being coplanar and/or a distance between element A and a reference element in a given direction being the same as a distance between element B and the reference element in the given direction. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

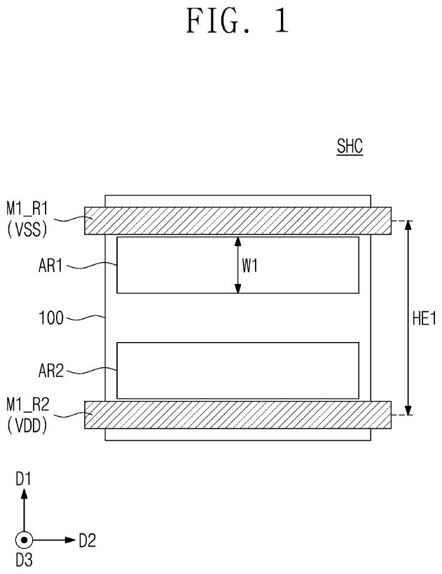

FIGS. 1 to 3 are conceptual diagrams illustrating logic cells of a semiconductor device according to some embodiments of the present disclosure.

Referring to FIG. 1, a single height cell SHC may be provided. In detail, a first power line M1_R1 and a second power line M1_R2 may be provided on a substrate 100. For example, the first power line M1_R1 may be a ground line VSS, and the second power line M1_R2 may be a power line VDD.

The single height cell SHC may be defined between the first power line M1_R1 and the second power line M1_R2. The single height cell SHC may include a first active region AR1 and a second active region AR2. One of the first and second active regions AR1 and AR2 may be a PMOSFET region, and the other may be an NMOSFET region. In other words, the single height cell SHC may have a CMOS structure provided between the first power line M1_R1 and the second power line M1_R2.

Each of the first and second active regions AR1 and AR2 may have a first width W1 in a first direction D1. The single height cell SHC may have a first height HE1 in the first direction D1. The first height HE1 may be substantially equal to a distance (e.g., a pitch) between the first power line M1_R1 and the second power line M1_R2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

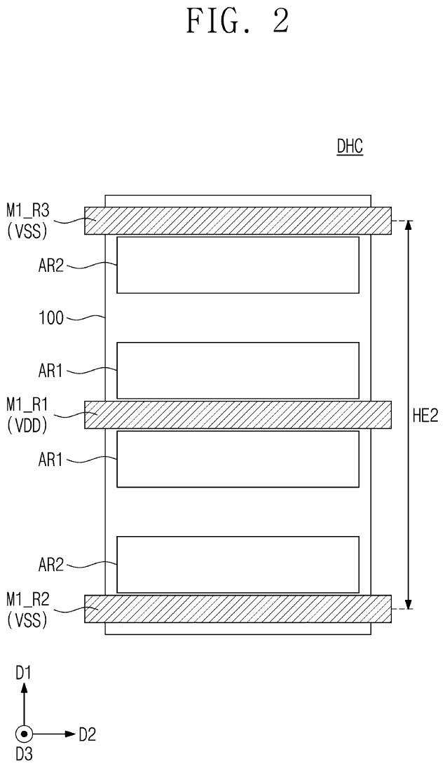

Referring to FIG. 2, a double height cell DHC may be provided. In detail, a first power line M1_R1, a second power line M1_R2, and a third power line M1_R3 may be provided on the substrate 100. The first power line M1_R1 may be disposed between the second power line M1_R2 and the third power line M1_R3. For example, the second and third power lines M1_R2 and M1_R3 may be the ground line VSS, and the first power line M1_R1 may be the power line VDD.

The double height cell DHC may be defined between the second power line M1_R2 and the third power line M1_R3. The double height cell DHC may include a pair of first active regions AR1 and a pair of second active regions AR2.

One of the pair of the second active regions AR2 may be adjacent to the second power line M1_R2. The other of the second active regions AR2 may be adjacent to the third power line M1_R3. The pair of the first active regions AR1 may be adjacent to the first power line M1_R1. When viewed in a plan view, the first power line M1_R1 may be disposed between the pair of the first active regions AR1.

The double height cell DHC may have a second height HE2 in the first direction D1. The second height HE2 may be about two times the first height HE1 of FIG. 1. The pair of the first active regions AR1 of the double height cell DHC may be combined to serve as a single active region.

In the present specification, the double height cell DHC may be defined as a multi-height cell. Although not shown, the multi-height cell may include a triple height cell whose cell height is about three times that of the single height cell SHC.

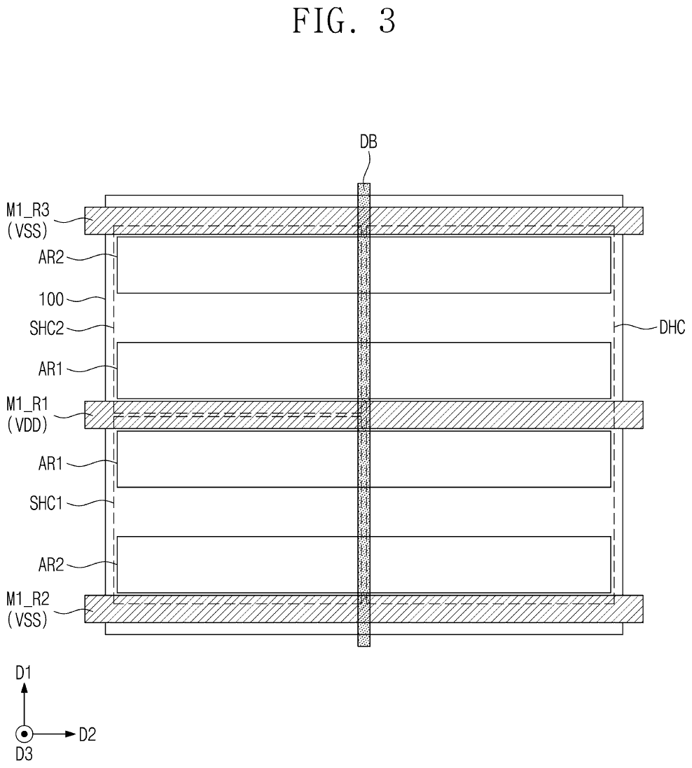

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

Division structures DB may be provided between the first single height cell SHC1 and the double height cell DHC and between the second single height cell SHC2 and the double height cell DHC. The division structures DB may electrically separate or insulate the active regions of the double height cell DHC from the active regions of the first and second single height cells SHC1 and SHC2.

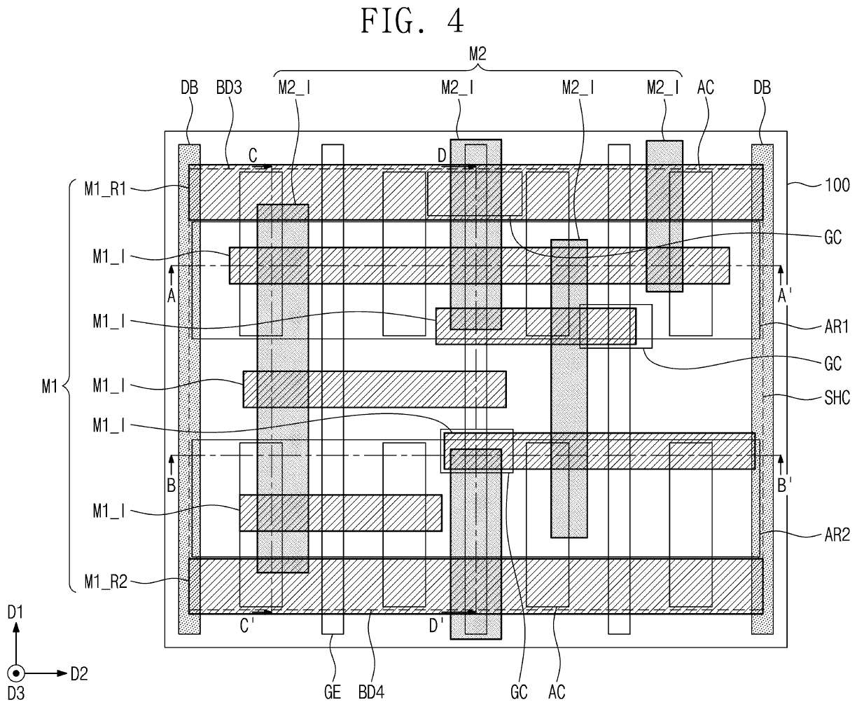

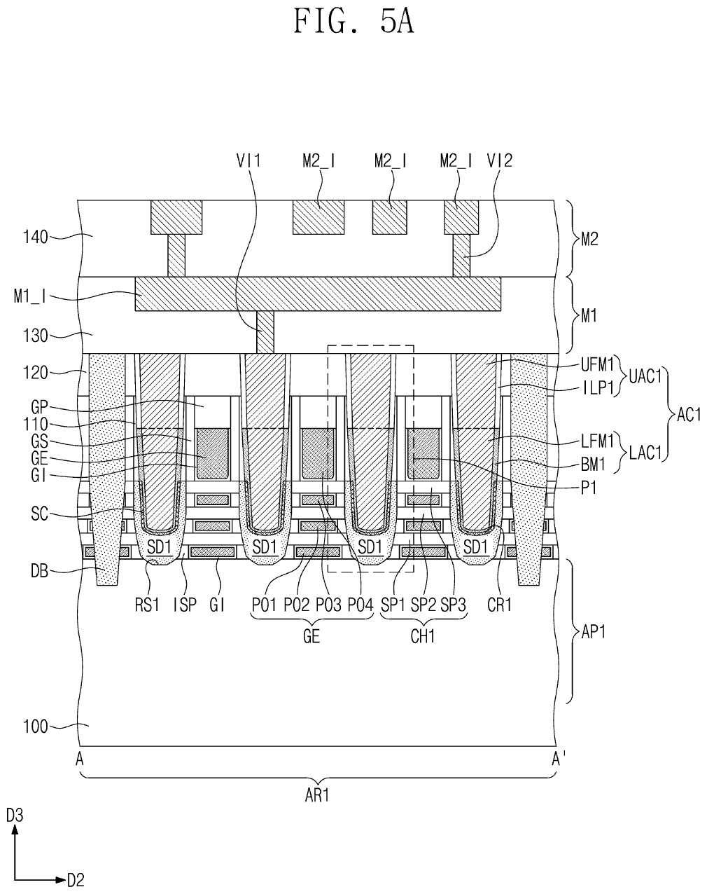

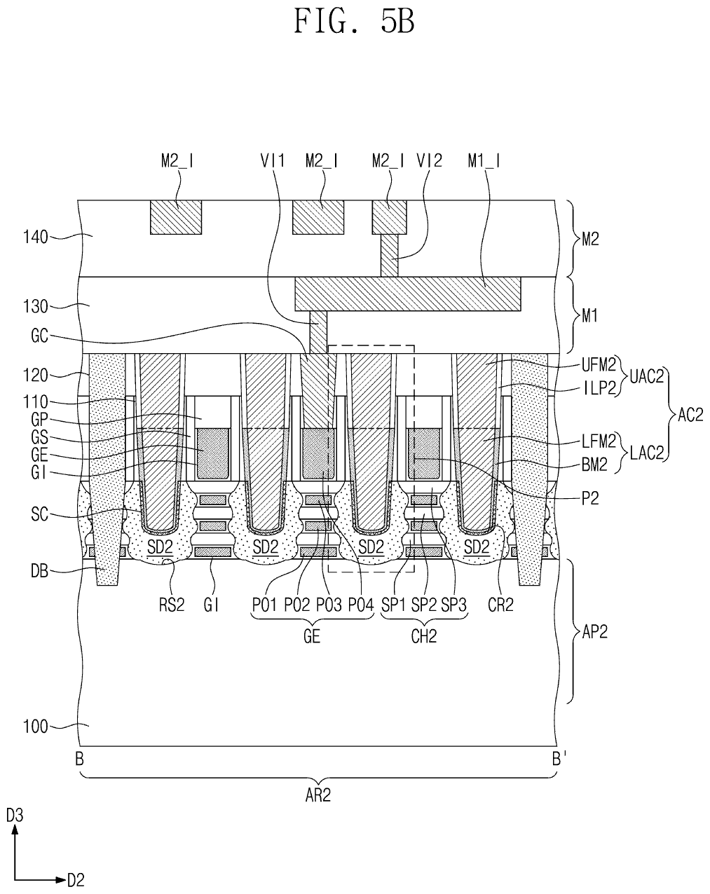

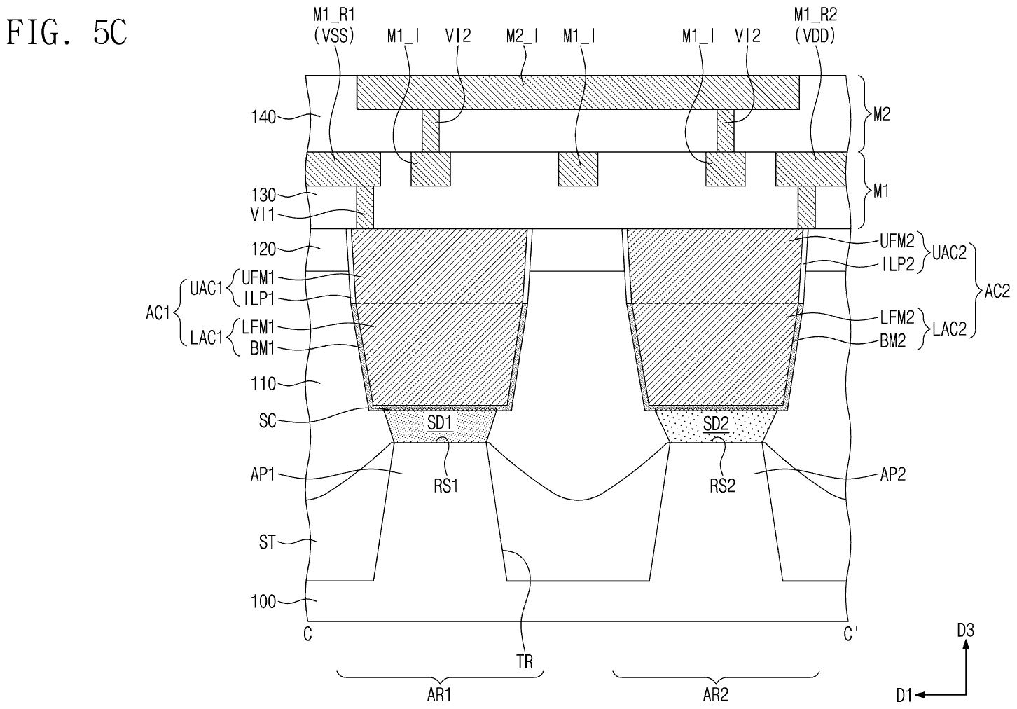

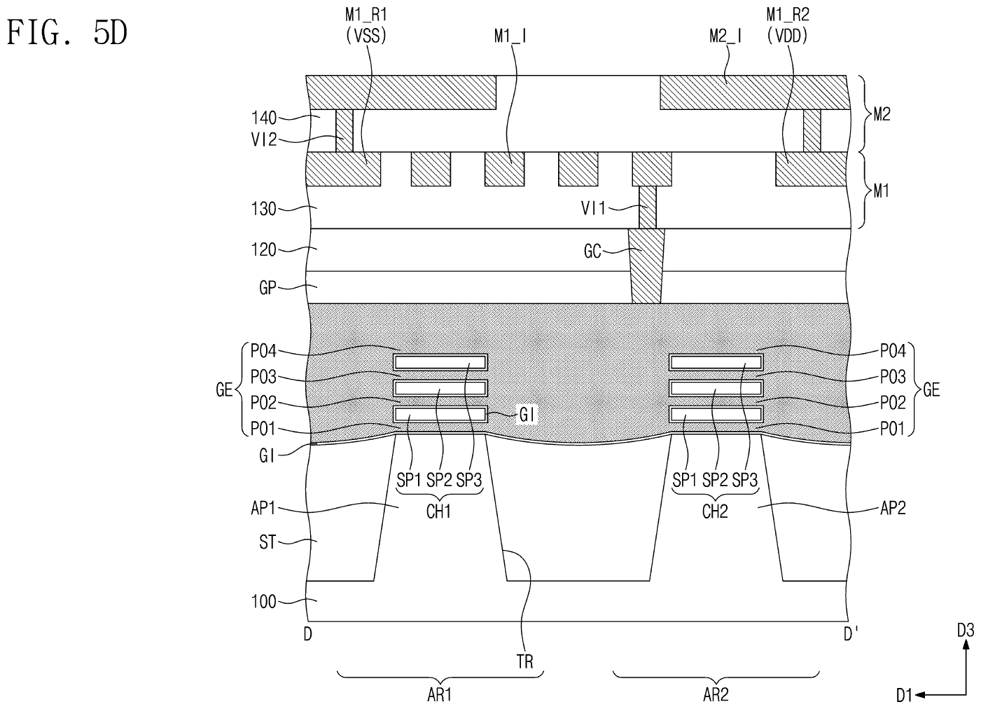

FIG. 4 is a plan view illustrating a semiconductor device according to some embodiments of the present disclosure. FIGS. 5A to 5D are sectional views taken along lines A-A′, B-B′, C-C′, and D-D′ of FIG. 4.

Referring to FIGS. 4 and 5A to 5D, the single height cell SHC may be provided on the substrate 100. The single height cell SHC may include logic transistors constituting a logic circuit. The substrate 100 may be a semiconductor substrate that is formed of or includes silicon, germanium, silicon germanium, a compound semiconductor material, or the like. For example, the substrate 100 may be a silicon substrate.

The substrate 100 may include the first active region AR1 and the second active region AR2. Each of the first and second active regions AR1 and AR2 may extend in the second direction D2. For example, the first active region AR1 may be an NMOSFET region, and the second active region AR2 may be a PMOSFET region.

A first active pattern AP1 and a second active pattern AP2 may be defined by a trench TR, which is formed in an upper portion of the substrate 100. The first active pattern AP1 may be provided on the first active region AR1, and the second active pattern AP2 may be provided on the second active region AR2. The first and second active patterns AP1 and AP2 may extend in the second direction D2. Each of the first and second active patterns AP1 and AP2 may be a vertically-protruding portion of the substrate 100.

A device isolation layer ST may be provided on the substrate 100. The device isolation layer ST may at least partially fill the trench TR. For example, the device isolation layer ST may include a silicon oxide layer or a silicon nitride layer. The device isolation layer ST may not cover or overlap first and second channel patterns CH1 and CH2, which will be described below.

First channel patterns CH1 may be provided on the first active pattern AP1. Second channel patterns CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon (e.g., single-crystalline silicon). In some embodiments, the first to third semiconductor patterns SP1, SP2, and SP3 may be nanosheets that are stacked.

First source/drain patterns SD1 may be provided on the first active pattern AP1. The first source/drain patterns SD1 may be provided in first recesses RS1, respectively, which are formed in an upper portion of the first active pattern AP1. The first source/drain patterns SD1 may be impurity regions of a first conductivity type (e.g., n-type). Each of the first channel patterns CH1 may be placed between a pair of the first source/drain patterns SD1. In other words, the pair of the first source/drain patterns SD1 may be electrically connected to each other by the first to third semiconductor patterns SP1, SP2, and SP3, which are stacked.

Second source/drain patterns SD2 may be provided on the second active pattern AP2. The second source/drain patterns SD2 may be provided in second recesses RS2, respectively, which are formed in an upper portion of the second active pattern AP2. The second source/drain patterns SD2 may be impurity regions of a second conductivity type (e.g., p-type). Each of the second channel patterns CH2 may be interposed between a pair of the second source/drain patterns SD2. In other words, the pair of the second source/drain patterns SD2 may be electrically connected to each other by the first to third semiconductor patterns SP1, SP2, and SP3, which are stacked.

The first and second source/drain patterns SD1 and SD2 may be epitaxial patterns, which are formed by a selective epitaxial growth (SEG) process. For example, a top surface of each of the first and second source/drain patterns SD1 and SD2 may be higher than a top surface of the third semiconductor pattern SP3 relative to the bottom surface of the substrate 100 in the third direction D3. In some embodiments, a top surface of at least one of the first and second source/drain patterns SD1 and SD2 may be located at substantially the same level (e.g., coplanar) as the top surface of the third semiconductor pattern SP3 relative to the bottom surface of the substrate 100 in the third direction D3.

In some embodiments, the first source/drain patterns SD1 may be formed of or include the same semiconductor element (e.g., Si) as the substrate 100. The second source/drain patterns SD2 may include a semiconductor material (e.g., SiGe) whose lattice constant is greater than that of the substrate 100. In this case, the pair of the second source/drain patterns SD2 may exert a compressive stress on the second channel patterns CH2.

In some embodiments, the second source/drain pattern SD2 may have an uneven or embossing side surface. For example, the side surface of the second source/drain pattern SD2 may have a wavy or nonlinear profile. That is, the side surface of the second source/drain pattern SD2 may protrude or extend toward first to third inner electrodes PO1, PO2, and PO3 of gate electrodes GE, which will be described below.

Gate electrodes GE may be provided on the first and second channel patterns CH1 and CH2, respectively. Each of the gate electrodes GE may extend in the first direction D1 to cross or intersect the first and second channel patterns CH1 and CH2. Each of the gate electrodes GE may be vertically overlapped with a corresponding one of the first and second channel patterns CH1 and CH2. The gate electrodes GE may be spaced apart from each other in the second direction D2.

Each of the gate electrodes GE may include a first inner electrode PO1 between the first or second active pattern AP1 or AP2 and the first semiconductor pattern SP1, a second inner electrode PO2 between the first semiconductor pattern SP1 and the second semiconductor pattern SP2, a third inner electrode PO3 between the second semiconductor pattern SP2 and the third semiconductor pattern SP3, and an outer electrode PO4 on the third semiconductor pattern SP3.

Each of the gate electrodes GE may be placed on a top surface, a bottom surface, and opposite side surfaces of each of the first to third semiconductor patterns SP1, SP2, and SP3. For example, each of the gate electrodes GE may be provided to at least partially surround the first to third semiconductor patterns SP1, SP2, and SP3. In some embodiments, the transistor according to the present embodiment may be a three-dimensional field effect transistor (e.g., MBCFET or GAAFET) in which the gate electrode GE is provided to three-dimensionally surround at least a portion of the channel pattern of the transistor.

On the first active region AR1, inner spacers ISP may be respectively provided between the first to third inner electrodes PO1, PO2, and PO3 of the gate electrodes GE and the first source/drain patterns SD1. Each of the first to third inner electrodes PO1, PO2, and PO3 of the gate electrodes GE may be spaced apart from the first source/drain patterns SD1 with the inner spacers ISP interposed therebetween. The inner spacers ISP may include an insulating material. Thus, the inner spacers ISP may prevent or inhibit a leakage current from the gate electrodes GE.

A pair of gate spacers GS may be provided on opposite side surfaces of the outer electrode PO4 of the gate electrodes GE. The gate spacers GS may extend along the gate electrodes GE and in the first direction D1. Top surfaces of the gate spacers GS may be higher than top surfaces of the gate electrodes GE relative to the bottom surface of the substrate 100 in the third direction D3. The top surfaces of the gate spacers GS may be coplanar with a top surface of a first interlayer insulating layer 110, which will be described below. For example, the gate spacers GS may include at least one of SiCN, SiCON, or SiN. Alternatively, the gate spacers GS may have a multi-layered structure including at least two of SiCN, SiCON, or SiN.

A gate capping pattern GP may be provided on each of the gate electrodes GE. The gate capping pattern GP may extend along the gate electrodes GE and in the first direction D1. The gate capping pattern GP may be formed of or include a material having an etch selectivity with respect to first and second interlayer insulating layers 110 and 120, which will be described below. For example, the gate capping pattern GP may be formed of or include at least one of SiON, SiCN, SiCON, or SiN.

A gate insulating layer GI may be provided between the gate electrodes GE and the first channel patterns CH1 and between the gate electrodes GE and the second channel patterns CH2. The gate insulating layer GI may cover or at least partially overlap a top surface, a bottom surface, and opposite side surfaces of each of the first to third semiconductor patterns SP1, SP2, and SP3. In addition, the gate insulating layer GI may cover or at least partially overlap a top surface of the device isolation layer ST below the gate electrodes GE.

In some embodiments, the gate insulating layer GI may include a silicon oxide layer, a silicon oxynitride layer, and/or a high-k dielectric layer. In some embodiments, the gate insulating layer GI may have a structure in which a silicon oxide layer and a high-k dielectric layer are stacked. In the present specification, the high-k dielectric layer may be a layer that is formed of or include a high-k dielectric material having a higher dielectric constant than the silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some embodiments, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected capacitors has a negative capacitance, a total capacitance of the serially-connected capacitors may have a positive value and may be greater than an absolute value of each capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. The hafnium zirconium oxide may be hafnium oxide doped with zirconium (Zr) or may be a compound of hafnium (Hf), zirconium (Zr), and oxygen (O).

The ferroelectric layer may further include dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric layer may vary depending on a ferroelectric material included in the ferroelectric layer. In the case where the ferroelectric layer includes hafnium oxide, the dopants may include at least one of gadolinium (Gd), silicon (Si), zirconium (Zr), aluminum (Al), or yttrium (Y).

The paraclectric layer may have the paraelectric property. For example, the paraelectric layer may include at least one of silicon oxide or metal oxide materials having high-k dielectric constants. The metal oxide materials for the paraelectric layer may include at least one of hafnium oxide, zirconium oxide, or aluminum oxide, but the present disclosure is not limited to this example.

The ferroelectric layer and the paraelectric layer may be formed of or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer. In addition, the ferroelectric layer may have a thickness capable of realizing a ferroelectric property. For example, the thickness of the ferroelectric layer may range from about 0.5 nm to about 10 nm. A critical thickness, at which the ferroelectric property occurs, may vary depending on the kind of the ferroelectric material.

In some embodiments, the gate insulating layer GI may include a single ferroelectric layer. In some embodiments, the gate insulating layer GI may include a plurality of ferroelectric layers that are spaced apart from each other. In some embodiments, the gate insulating layer GI may be provided to have a multi-layered structure, in which a plurality of ferroelectric layers and a plurality of paraelectric layers are alternately stacked.

A first interlayer insulating layer 110 may be provided on the first and second source/drain patterns SD1 and SD2. The first interlayer insulating layer 110 may cover or at least partially overlap the gate spacers GS and the first and second source/drain patterns SD1 and SD2. A top surface of the first interlayer insulating layer 110 may be substantially coplanar with the top surface of the gate capping pattern GP and the top surfaces of the gate spacers GS.

Second to fourth interlayer insulating layers 120, 130, and 140 may be sequentially provided on the first interlayer insulating layer 110. The second interlayer insulating layer 120 may cover or at least partially overlap the gate capping pattern GP and the first interlayer insulating layer 110. The third interlayer insulating layer 130 may be provided on the second interlayer insulating layer 120, and the fourth interlayer insulating layer 140 may be provided on the third interlayer insulating layer 130. For example, the first to fourth interlayer insulating layers 110, 120, 130, and 140 may include a silicon oxide layer.

A pair of division structures DB, which are opposite to each other in the second direction D2, may be provided at both sides of the single height cell SHC. For example, a pair of the division structures DB may be provided on a border of the single height cell SHC. The division structures DB may extend in the first direction D1 to be parallel to the gate electrodes GE.

The division structure DB may be provided to penetrate or extend into the first and second interlayer insulating layers 110 and 120 and may extend into the first and second active patterns AP1 and AP2. The division structure DB may be provided to penetrate or extend into an upper portion of each of the first and second active patterns AP1 and AP2. In the case where a plurality of single height cells SHC are provided, the division structures DB may be used to electrically separate or insulate adjacent ones of the single height cell SHC from each other.

First active contacts AC1 and second active contacts AC2 may be provided to penetrate or extend into the first and second interlayer insulating layers 110 and 120. For example, the first active contacts AC1 may be placed on the first active region AR1, and the second active contacts AC2 may be placed on the second active region AR2. Each of the first active contacts AC1 may be connected to a corresponding one of the first source/drain patterns SD1. Each of the second active contacts AC2 may be connected to a corresponding one of the second source/drain patterns SD2. The gate electrodes GE may be placed at both sides of each of the first and second active contacts AC1 and AC2. When viewed in a plan view, each of the first and second active contacts AC1 and AC2 may be a bar-shaped pattern extending in the first direction D1.

In some embodiments, each of the first and second active contacts AC1 and AC2 may be a self-aligned contact. For example, each of the first and second active contacts AC1 and AC2 may be formed by a self-aligned method using the gate capping pattern GP and the gate spacers GS. Thus, each of the first and second active contacts AC1 and AC2 may cover or overlap a portion of a side surface of the gate spacer GS, but the present disclosure is not limited to this example.

Each of the first active contacts AC1 may include a first lower active contact LAC1 and a first upper active contact UAC1. The first lower active contact LAC1 may include a first barrier pattern BM1 and a first lower metal pattern LFM1. The first upper active contact UAC1 may be placed on the first lower active contact LAC1 and may include a first insulating pattern ILP1 and a first upper metal pattern UFM1.

Each of the second active contacts AC2 may include a second lower active contact LAC2 and a second upper active contact UAC2. The second lower active contact LAC2 may include a second barrier pattern BM2 and a second lower metal pattern LFM2. The second upper active contact UAC2 may be placed on the second lower active contact LAC2 and may include a second insulating pattern ILP2 and a second upper metal pattern UFM2.

Metal-semiconductor compound layers SC may be provided between the first active contacts AC1 and the first source/drain patterns SD1 and between the second active contacts AC2 and the second source/drain patterns SD2. The first and second active contacts AC1 and AC2 may be electrically connected to the first and second source/drain patterns SD1 and SD2, respectively, through the metal-semiconductor compound layers SC.

Gate contacts GC may be provided to penetrate or extend into the second interlayer insulating layer 120 and the gate capping pattern GP. The gate contacts GC may be connected to the gate electrodes GE, respectively. When viewed in a plan view, the gate contacts GC may be overlapped by the first active region AR1 and the second active region AR2, but the present disclosure is not limited to this example.

A first metal layer M1 may be provided in the third interlayer insulating layer 130. The first metal layer M1 may include the first power line M1_R1, the second power line M1_R2, and first interconnection lines M1_I. The interconnection lines M1_R1, M1_R2, and M1_I of the first metal layer M1 may extend in the second direction D2 and parallel to each other. When viewed in a plan view, the first interconnection lines M1_I of the first metal layer M1 may be disposed between the first and second power lines M1_R1 and M1_R2. The first metal layer M1 may further include first vias VI1. The first vias VI1 may be placed below the interconnection lines M1_R1, M1_R2, and M1_I of the first metal layer M1 and may be connected to one of the first and second active contacts AC1 and AC2 and the gate contacts GC. The interconnection lines M1_R1, M1_R2, and M1_I of the first metal layer M1 may be electrically connected to the first and second active contacts AC1 and AC2 and the gate contacts GC through the first vias VI1.

A second metal layer M2 may be provided in the fourth interlayer insulating layer 140. The second metal layer M2 may include a plurality of second interconnection lines M2_I. Each of the second interconnection lines M2_I of the second metal layer M2 may be a line-shaped or bar-shaped pattern that extends in the first direction D1. In other words, the second interconnection lines M2_I may extend in the first direction D1 to be parallel to each other. The second metal layer M2 may further include second vias VI2 provided below the second interconnection lines M2_I. The interconnection lines M1_R1, M1_R2, and M1_I of the first metal layer M1 and the second interconnection lines M2_I of the second metal layer M2 may be electrically connected to each other through the second vias VI2.

In some embodiments, the interconnection lines M1_R1, M1_R2, and M1_I of the first metal layer M1 and the second interconnection lines M2_I of the second metal layer M2 may be formed of or include the same conductive material or different conductive materials. For example, the interconnection lines M1_R1, M1_R2, and M1_I of the first metal layer M1 and the second interconnection lines M2_I of the second metal layer M2 may include at least one of metallic materials (e.g., aluminum (Al), copper (Cu), tungsten (W), molybdenum (Mo), ruthenium (Ru), and/or cobalt (Co)).

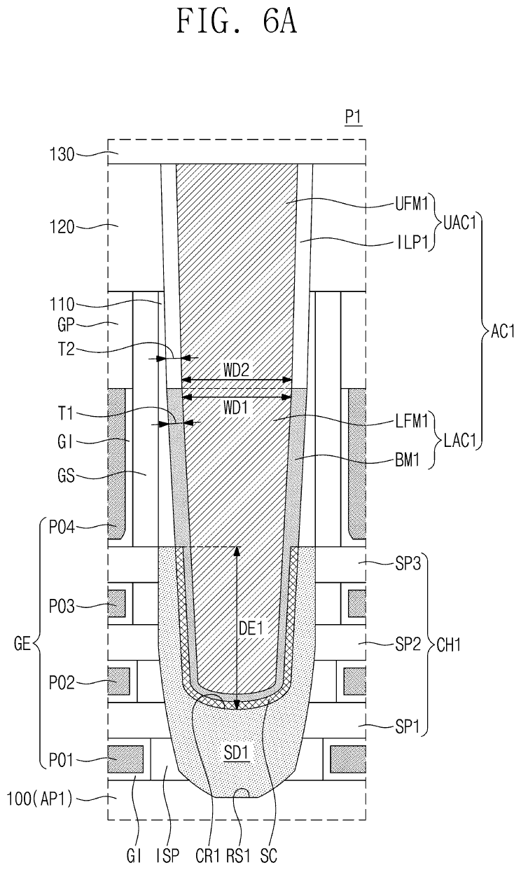

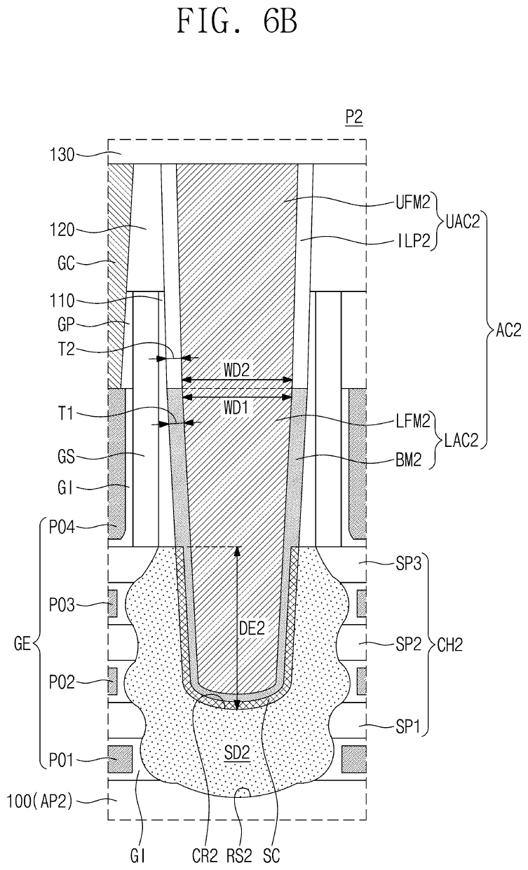

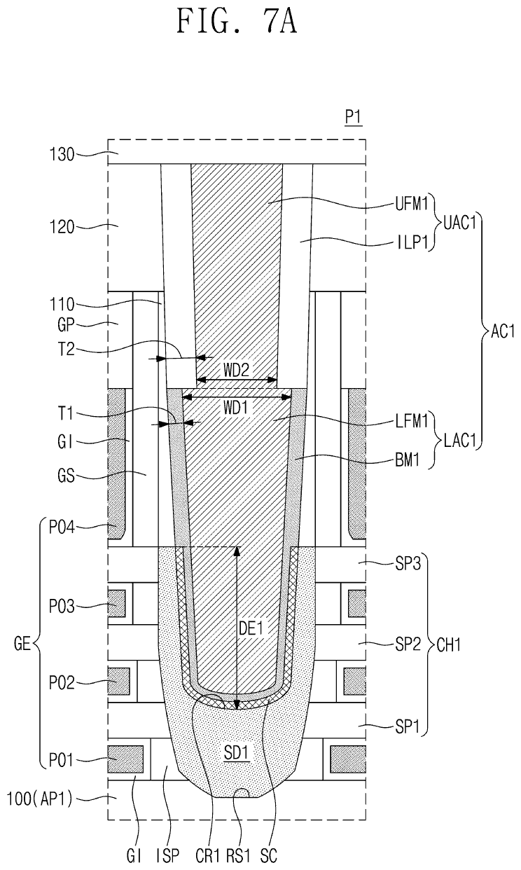

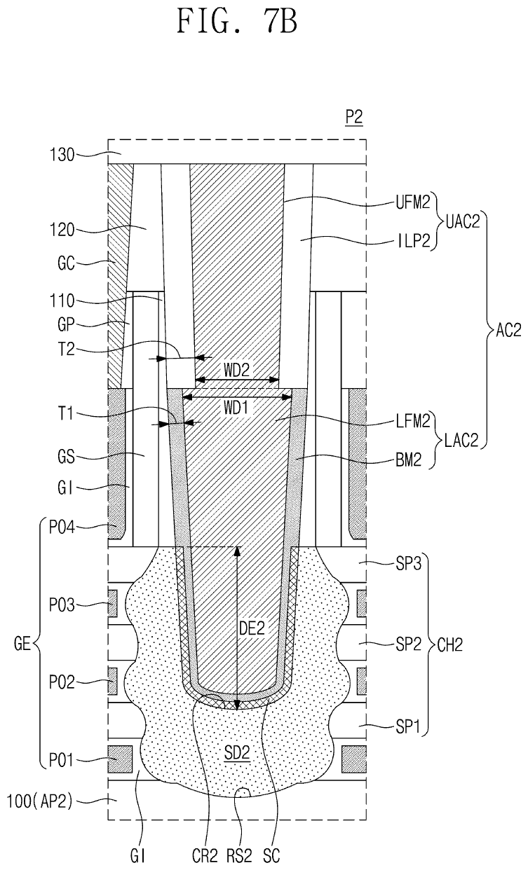

FIG. 6A is an enlarged sectional view illustrating a portion ‘P1’ of FIG. 5A. FIG. 6B is an enlarged sectional view illustrating a portion ‘P2’ of FIG. 5B. FIG. 7A is an enlarged sectional view illustrating the portion ‘P1’ of FIG. 5A. FIG. 7B is an enlarged sectional view illustrating the portion ‘P2’ of FIG. 5B.

Referring to FIGS. 6A and 6B, the first active contact AC1 may include the first lower active contact LAC1, which includes the first barrier pattern BM1 and the first lower metal pattern LFM1, and the first upper active contact UAC1, which includes the first upper metal pattern UFM1 and the first insulating pattern ILP1. The second active contact AC2 may include the second lower active contact LAC2, which includes the second barrier pattern BM2 and the second lower metal pattern LFM2, and the second upper active contact UAC2, which includes the second upper metal pattern UFM2 and the second insulating pattern ILP2.

The first source/drain pattern SD1 may be provided to have a first contact recess CR1 therein, and the first lower active contact LAC1 may be placed in the first contact recess CR1. The first contact recess CR1 of the first source/drain pattern SD1 may have a first depth DE1 from a top surface of the first source/drain pattern SD1 in a vertical direction. For example, a bottom surface of the first contact recess CR1 may be placed at a level lower than the second semiconductor pattern SP2 of the first channel pattern CH1 relative to the bottom surface of the substrate 100 in the third direction D3. In other words, the first lower active contact LAC1 may be provided to penetrate or extend into a portion of the first source/drain pattern SD1, and a bottom end of the first lower active contact LAC1 may be located at a level that is lower than the second semiconductor pattern SP2 of the first channel pattern CH1 relative to the bottom surface of the substrate 100 in the third direction D3.

The second source/drain pattern SD2 may be provided to have a second contact recess CR2 therein, and the second lower active contact LAC2 may be placed in the second contact recess CR2. The second contact recess CR2 of the second source/drain pattern SD2 may have a second depth DE2 from a top surface of the second source/drain pattern SD2 in a vertical direction. The second depth DE2 may be substantially equal to the first depth DE1 of the first contact recess CR1, but the present disclosure is not limited to this example. For example, a bottom surface of the second contact recess CR2 may be located at a level lower than the second semiconductor pattern SP2 of the second channel pattern CH2 relative to the bottom surface of the substrate 100 in the third direction D3. In other words, the second lower active contact LAC2 may be provided to penetrate or extend into a portion of the second source/drain pattern SD2, and a bottom end of the second lower active contact LAC2 may be located at a level that is lower than the second semiconductor pattern SP2 of the second channel pattern CH2 relative to the bottom surface of the substrate 100 in the third direction D3.

The first barrier pattern BM1 may be placed in the first contact recess CR1 of the first source/drain pattern SD1 and may cover or at least partially overlap side and bottom surfaces of the first lower metal pattern LFM1. That is, the first barrier pattern BM1 may be in contact with the first lower metal pattern LFM1 and may enclose or at least partially surround the first lower metal pattern LFM1. For example, the first barrier pattern BM1 may have a U-shaped structure, when viewed in a sectional view. The first barrier pattern BM1 may have a first thickness T1 in a direction perpendicular to a side surface of the first lower metal pattern LFM1.

The second barrier pattern BM2 may have substantially the same structure as the first barrier pattern BM1. That is, the second barrier pattern BM2 may have a U-shaped structure, when viewed in a sectional view, and may enclose or at least partially surround the second lower metal pattern LFM2. The second barrier pattern BM2 may have substantially the same thickness (e.g., the first thickness T1) as the first barrier pattern BM1. The first and second barrier patterns BM1 and BM2 may be formed of or include at least one of, for example, titanium nitride (TiN), tantalum nitride (TaN), molybdenum nitride (MoN), platinum nitride (PtN), tungsten nitride (WN), nickel nitride (NiN), iridium nitride (IrN), rhodium nitride (RhN), or cobalt nitride (CON).

The first and second lower metal patterns LFM1 and LFM2 may be placed on the first and second barrier patterns BM1 and BM2, respectively. For example, the first lower metal pattern LFM1 may be provided to at least partially fill an inner space of the U-shaped structure of the first barrier pattern BM1. The second lower metal pattern LFM2 may be provided to at least partially fill an inner space of the U-shaped structure of the second barrier pattern BM2. The first and second lower metal patterns LFM1 and LFM2 may have substantially the same width (e.g., a first width WD1) at their top level. In some embodiments, the first and second lower metal patterns LFM1 and LFM2 may be formed of or include at least one of titanium (Ti), tantalum (Ta), molybdenum (Mo), platinum (Pt), tungsten (W), nickel (Ni), iridium (Ir), rhodium (Rh), or cobalt (Co).

The first upper active contact UAC1 may be placed on the first lower active contact LAC1, and the first insulating pattern ILP1 of the first upper active contact UAC1 may be placed on side surfaces of the first upper metal pattern UFM1. The first insulating pattern ILP1 may enclose or at least partially surround the side surfaces of the first upper metal pattern UFM1 with a uniform thickness. Here, the first insulating pattern ILP1 may not extend to a region below a bottom surface of the first upper metal pattern UFM1. The first insulating pattern ILP1 may have a second thickness T2 in a direction perpendicular to the side surface of the first upper metal pattern UFM1. The second thickness T2 of the first insulating pattern ILP1 may be substantially equal to the first thickness T1 of the first barrier pattern BM1.

The second upper active contact UAC2 may be placed on the second lower active contact LAC2 and may have substantially the same structure as the first upper active contact UAC1. That is, the second insulating pattern ILP2 of the second upper active contact UAC2 may be provided on side surfaces of the second upper metal pattern UFM2 and may enclose or at least partially surround the side surfaces of the second upper metal pattern UFM2 with a uniform thickness. The second insulating pattern ILP2 may have substantially the same thickness (e.g., the second thickness T2) as the first insulating pattern ILP1. In addition, the second thickness T2 of the second insulating pattern ILP2 may be substantially equal to the first thickness T1 of the second barrier pattern BM2. In some embodiments, the first and second insulating patterns ILP1 and ILP2 may be formed of or include at least one of SiO, SiON, SiCN, SiCON, or SiN.

The first and second upper metal patterns UFM1 and UFM2 may be placed on the first and second lower metal patterns LFM1 and LFM2, respectively. The first upper metal pattern UFM1 and the first lower metal pattern LFM1 may be in contact with each other. The second upper metal pattern UFM2 and the second lower metal pattern LFM2 may be in contact with each other. The first and second upper metal patterns UFM1 and UFM2 may have substantially the same width (e.g., second width WD2) at their bottom level. The second width WD2 of the first upper metal pattern UFM1 may be substantially equal to the first width WD1 of the first lower metal pattern LFM1, and the second width WD2 of the second upper metal pattern UFM2 may be substantially equal to the first width WD1 of the second lower metal pattern LFM2. In some embodiments, the first and second upper metal patterns UFM1 and UFM2 may be formed of or include at least one of titanium (Ti), tantalum (Ta), molybdenum (Mo), platinum (Pt), tungsten (W), nickel (Ni), iridium (Ir), rhodium (Rh), or cobalt (Co).

In some embodiments, each of the first and second upper metal patterns UFM1 and UFM2 may be formed from the first and second lower metal patterns LFM1 and LFM2 through a selective growth process. The first upper metal pattern UFM1 may include substantially the same material as the first lower metal pattern LFM1, and the second upper metal pattern UFM2 may include substantially the same material as the second lower metal pattern LFM2. In this case, an interface between the first upper metal pattern UFM1 and the first lower metal pattern LFM1 and an interface between the second upper metal pattern UFM2 and the second lower metal pattern LFM2 may not be visible or observable.

The metal-semiconductor compound layers SC may be respectively provided between the first active contact AC1 and the first source/drain pattern SD1 and between the second active contact AC2 and the second source/drain pattern SD2. The metal-semiconductor compound layers SC may cover or at least partially overlap the first contact recess CR1 of the first source/drain pattern SD1 and the second contact recess CR2 of the second source/drain pattern SD2 with a uniform thickness. For example, the metal-semiconductor compound layers SC may be formed from the first and second barrier patterns BM1 and BM2 through a thermal treatment process. Thus, the first and second barrier patterns BM1 and BM2 may have a relatively small thickness in the first and second contact recesses CR1 and CR2, respectively. For example, the metal-semiconductor compound layers SC may be formed of or include at least one of titanium silicide, tantalum silicide, molybdenum silicide, platinum silicide, tungsten silicide, nickel silicide, iridium silicide, rhodium silicide, or cobalt silicide.

In some embodiments, the first and second active contacts AC1 and AC2 may be electrically connected to the first and second source/drain patterns SD1 and SD2, respectively, through the metal-semiconductor compound layers SC. Due to the metal-semiconductor compound layers SC, a contact resistance between the first and second active contacts AC1 and AC2 and the first and second source/drain patterns SD1 and SD2 may be reduced. Thus, the electrical characteristics of the semiconductor device may be improved.

Referring to FIGS. 7A and 7B, the first thickness T1 of the first barrier pattern BM1 may be smaller than the second thickness T2 of the first insulating pattern ILP1. The second barrier pattern BM2 may have substantially the same thickness (e.g., the first thickness T1) as the first barrier pattern BM1. In addition, the second insulating pattern ILP2 may have substantially the same thickness (e.g., the second thickness T2) as the first insulating pattern ILP1. That is, the first thickness T1 of the second barrier pattern BM2 may be smaller than the second thickness T2 of the second insulating pattern ILP2. Thus, the first insulating pattern ILP1 may cover or overlap a portion of a top surface of the first lower metal pattern LFM1, and the second insulating pattern ILP2 may cover or overlap a portion of a top surface of the second lower metal pattern LFM2. Thus, the first upper metal pattern UFM1 may be spaced apart from the first barrier pattern BM1, and the second upper metal pattern UFM2 may be spaced apart from the second barrier pattern BM2.

Since the thickness of the first insulating pattern ILP1 is larger than that of the first barrier pattern BM1, a top width (e.g., the first width WD1) of the first lower metal pattern LFM1 may be larger than a bottom width (e.g., the second width WD2) of the first upper metal pattern UFM1. The second lower metal pattern LFM2 may have substantially the same width (e.g., the first width WD1) as the first lower metal pattern LFM1 at its top level, and the second upper metal pattern UFM2 may have substantially the same width (e.g., the second width WD2) as the first upper metal pattern UFM1 at its bottom level. In other words, the first width WD1 of the second lower metal pattern LFM2 may be larger than the second width WD2 of the second upper metal pattern UFM2.

Referring back to FIGS. 6A to 7B, the first and second lower active contacts LAC1 and LAC2 of the semiconductor device may exert a stress on the first and second channel patterns CH1 and CH2, respectively. In some embodiments, the first active region AR1 of FIGS. 5A to 5D may be an NMOSFET region, and the second active region AR2 may be a PMOSFET region. The first and second lower metal patterns LFM1 and LFM2 may include tungsten (W), the first lower metal pattern LFM1 may further include fluorine (F), and the second lower metal pattern LFM2 may further include argon (Ar). In this case, the fluorine (F) may serve as a substitutional defect, and the argon (Ar) may serve as an interstitial defect. Accordingly, the first lower metal pattern LFM1 may exert a tensile stress on the first channel pattern CH1. The second lower metal pattern LFM2 may exert a compressive stress on the second channel pattern CH2. Thus, the carrier mobility of the first to third semiconductor patterns SP1, SP2, and SP3 of the first and second channel patterns CH1 and CH2 may be increased. Thus, the electrical characteristics of the semiconductor device may be improved.

In addition, the first and second lower metal patterns LFM1 and LFM2 may be in contact with the first and second upper metal patterns UFM1 and UFM2, respectively. The first and second lower metal patterns LFM1 and LFM2 may include substantially the same material as the first and second upper metal patterns UFM1 and UFM2. Thus, a contact resistance between the first and second lower active contacts LAC1 and LAC2 and the first and second upper active contacts UAC1 and UAC2 may be reduced. Thus, the electrical characteristics of the semiconductor device may be improved.

In addition, thicknesses of the first and second insulating patterns ILP1 and ILP2 may be substantially equal to or larger than the first and second barrier patterns BM1 and BM2, respectively. Widths of the first and second upper metal patterns UFM1 and UFM2 may depend on the thicknesses of the first and second insulating patterns ILP1 and ILP2. The first and second insulating patterns ILP1 and ILP2 may cover or at least partially overlap top surfaces of the first and second barrier patterns BM1 and BM2. Thus, the first and second upper metal patterns UFM1 and UFM2 may be easily formed from the first and second lower metal patterns LFM1 and LFM2. Thus, the electrical characteristics of the semiconductor device may be improved.

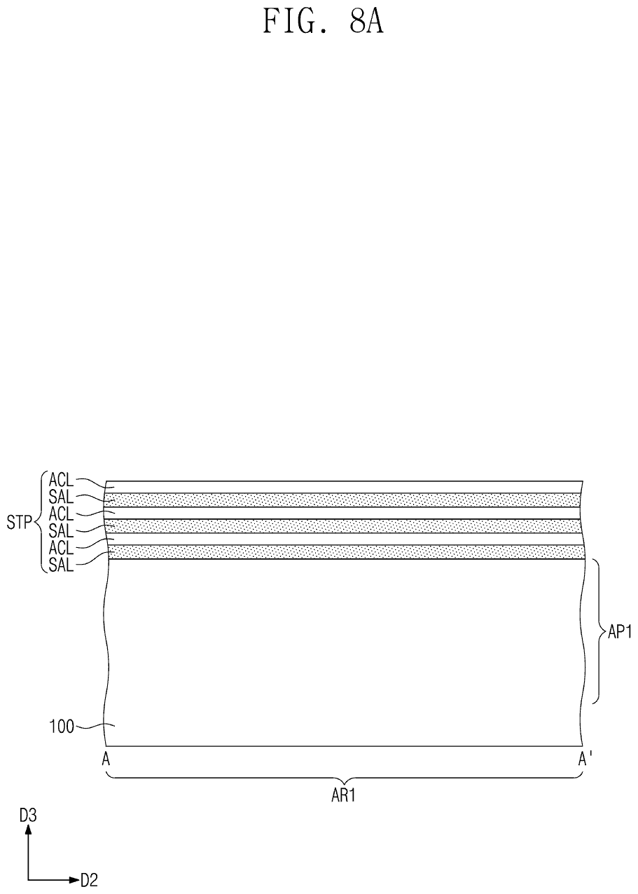

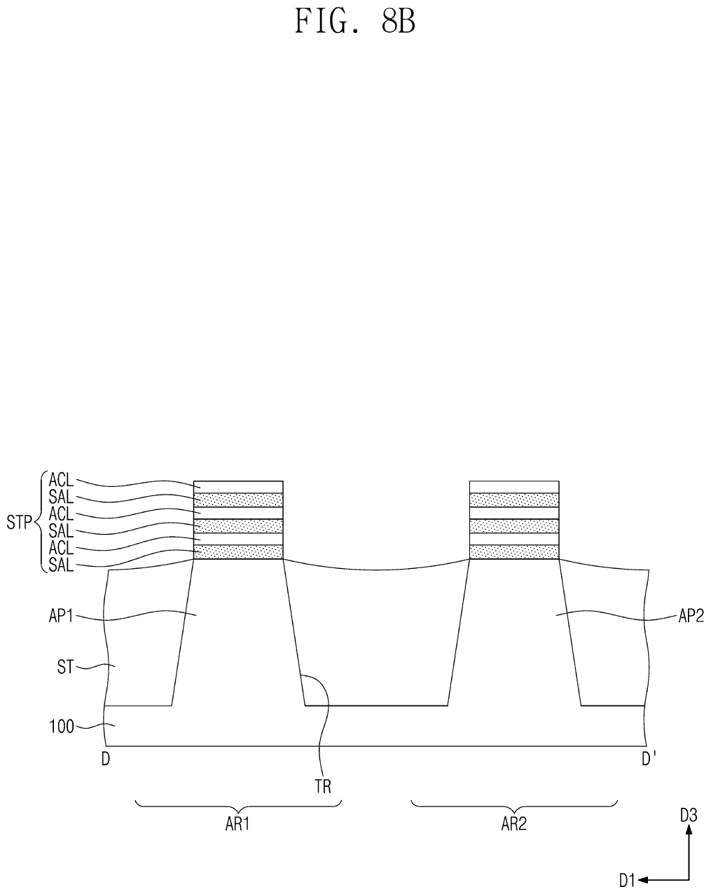

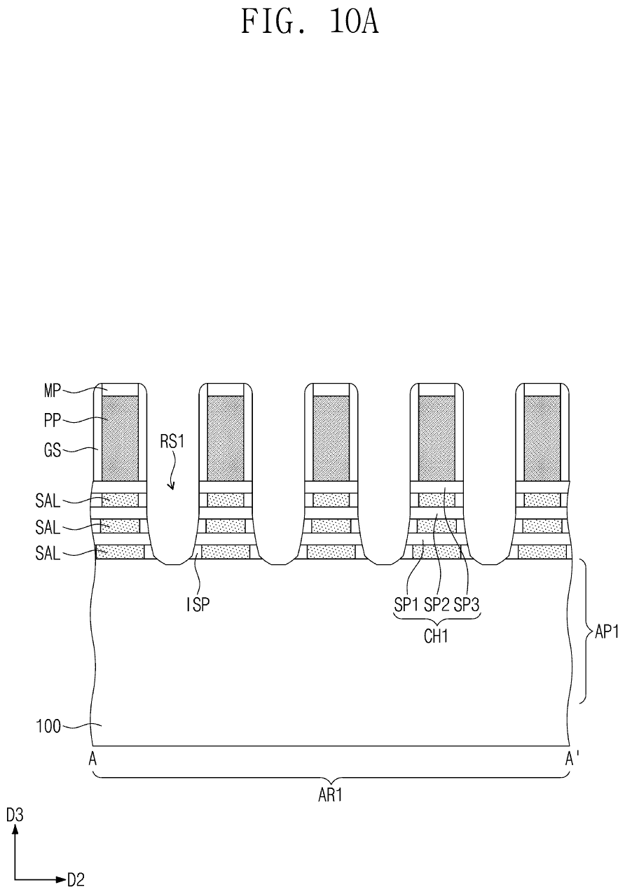

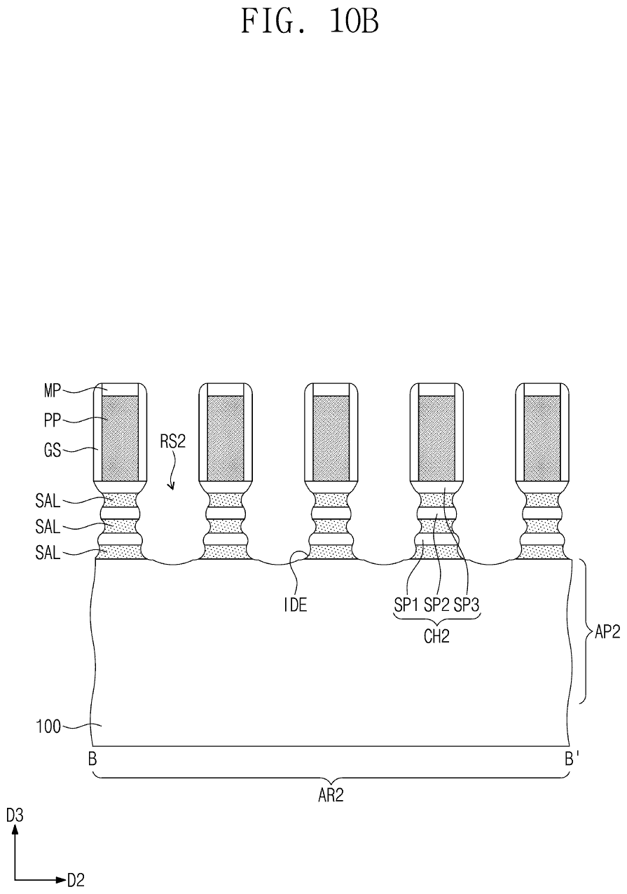

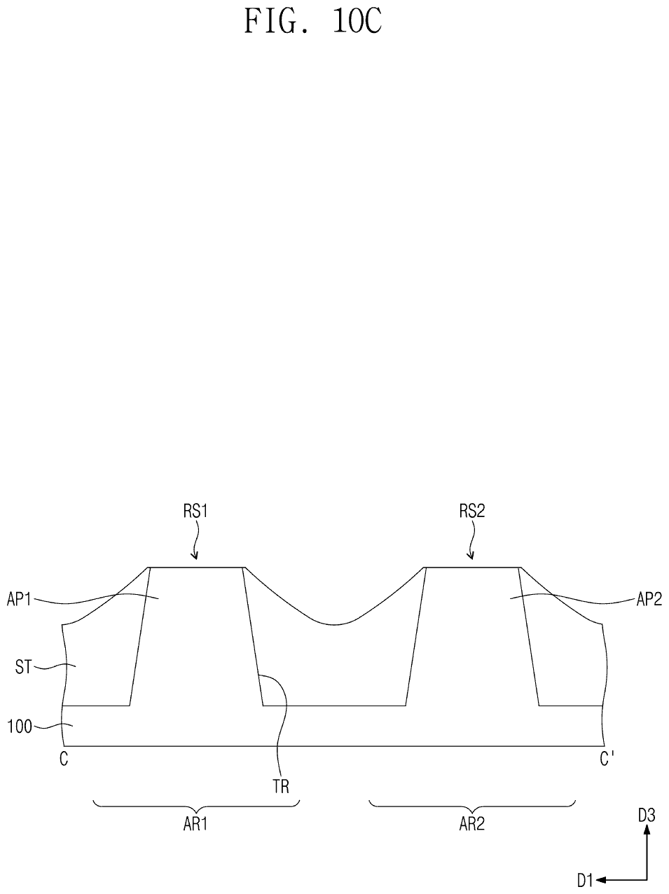

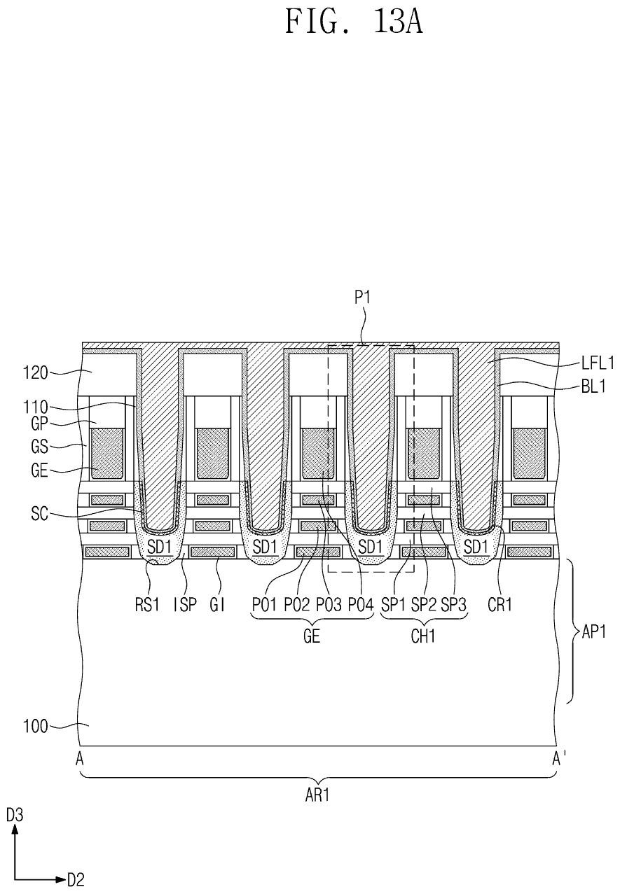

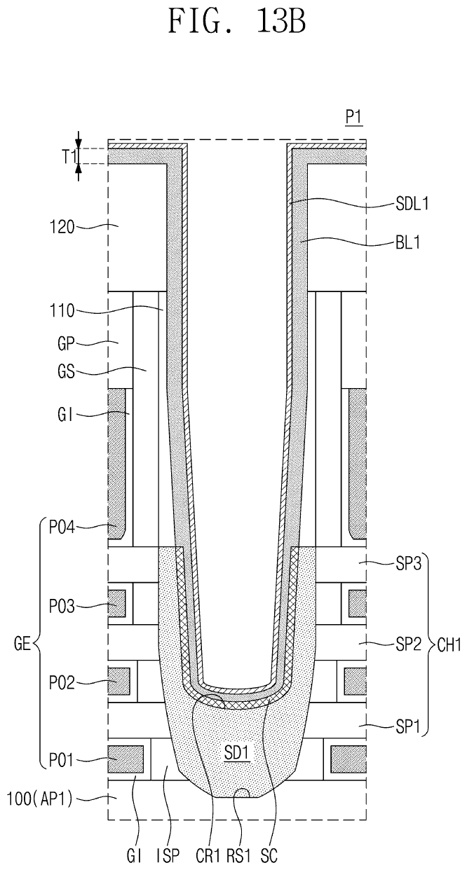

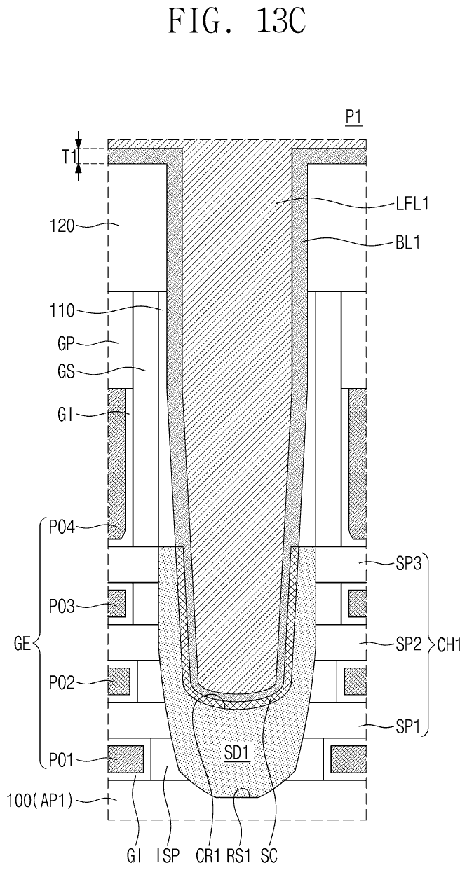

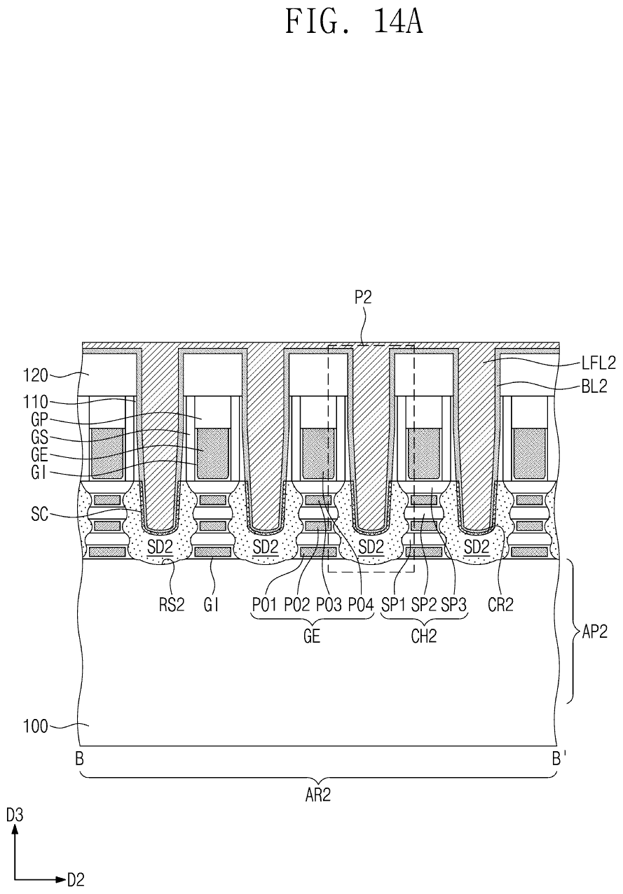

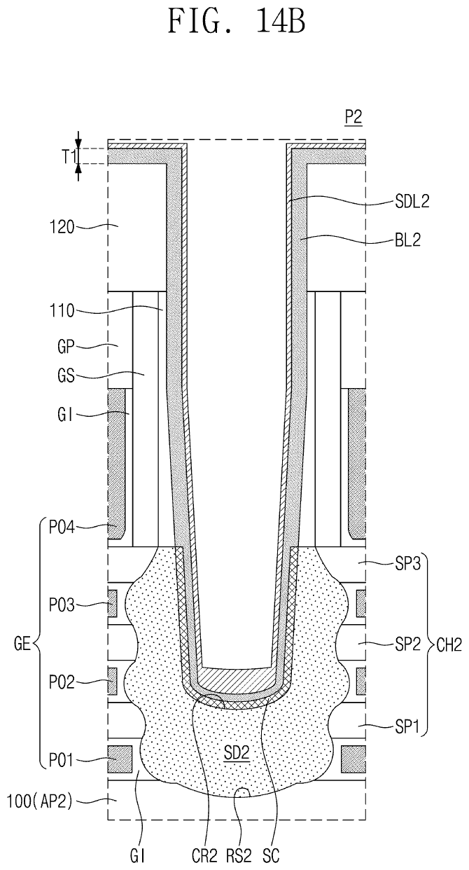

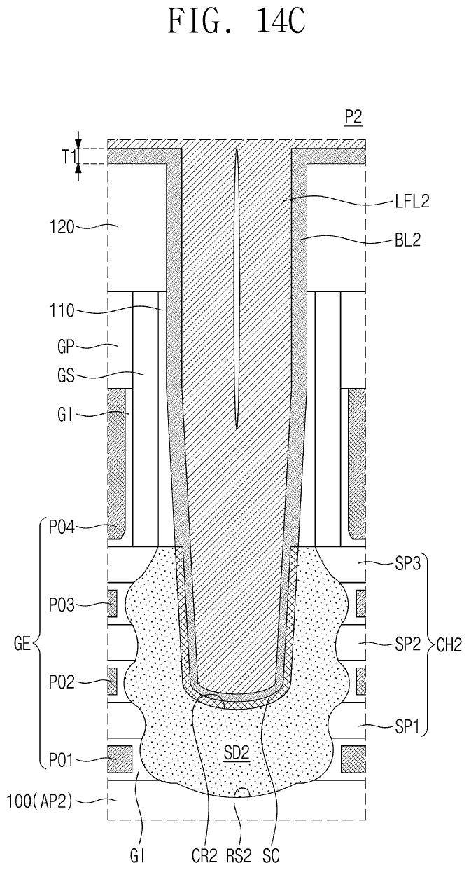

FIGS. 8A to 16B are sectional views illustrating a method of fabricating a semiconductor device, according to some embodiments of the present disclosure. FIGS. 8A, 9A, 10A, 11A, 12A, 13A, 15A, and 16A are sectional views taken along the line A-A of FIG. 4. FIGS. 10B, 11B, 12B, 14A, 15B, and 16B are sectional views taken along the line B-B′ of FIG. 4. FIGS. 10C, 11C, and 12C are sectional views taken along the line C-C′ of FIG. 4. FIGS. 8B, 9B, 11D, and 12D are sectional views taken along the line D-D′ of FIG. 4. FIGS. 13B and 13C are enlarged sectional views illustrating a portion ‘P1’ of FIG. 13A, and FIGS. 14B and 14C are enlarged sectional views illustrating a portion ‘P1’ of FIG. 14A.

Referring to FIGS. 8A and 8B, the substrate 100 including the first and second active regions AR1 and AR2 may be provided. Active layers ACL and sacrificial layers SAL, which are alternately stacked, may be formed on the substrate 100. The active layers ACL and the sacrificial layers SAL may be formed of or include at least one of silicon (Si), germanium (Ge), or silicon germanium (SiGe), and the active layers ACL and the sacrificial layers SAL may be formed of different materials from each other.

In some embodiments, the sacrificial layers SAL may include a material having an etch selectivity with respect to the active layers ACL. For example, the active layers ACL may be formed of or include silicon (Si), and the sacrificial layers SAL may be formed of or include silicon germanium (SiGe). A germanium concentration of each of the sacrificial layers SAL may range from about 10 at % to about 30 at %.

Next, mask patterns may be formed on the first and second active regions AR1 and AR2 of the substrate 100, respectively. The mask pattern may be a line-shaped or bar-shaped pattern extending in the second direction D2. A patterning process using the mask patterns as an etch mask may be performed to form the trench TR defining the first active pattern AP1 and the second active pattern AP2. The first active pattern AP1 may be formed on the first active region AR1. The second active pattern AP2 may be formed on the second active region AR2.

Stacking patterns STP may be formed on the first and second active patterns AP1 and AP2, respectively. The stacking patterns STP may include the active layers ACL and the sacrificial layers SAL, which are alternately stacked on top of each other. The stacking patterns STP as well as the first and second active patterns AP1 and AP2 may be formed through the patterning process of forming the trench TR. After the formation of the stacking patterns STP, the device isolation layer ST may be formed to at least partially fill the trench TR.

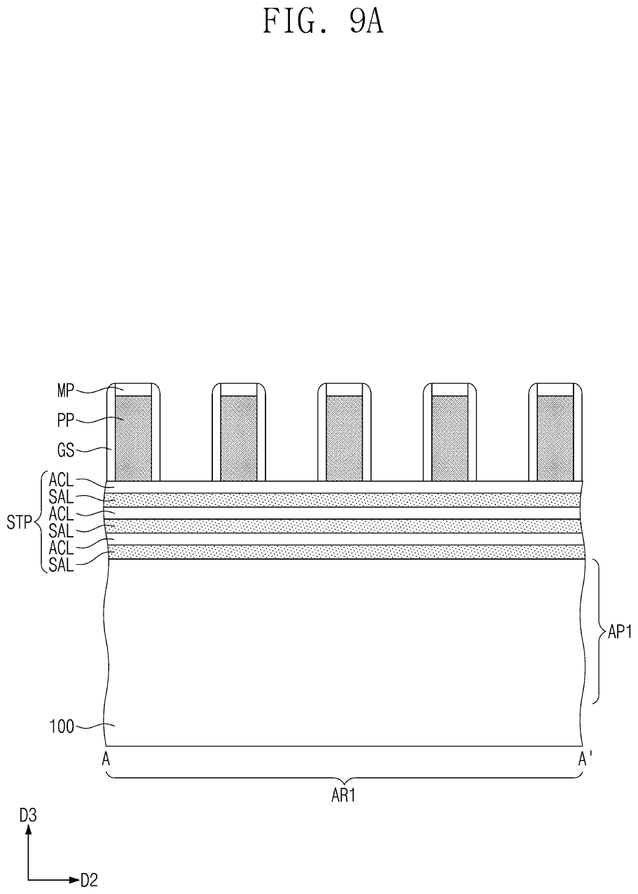

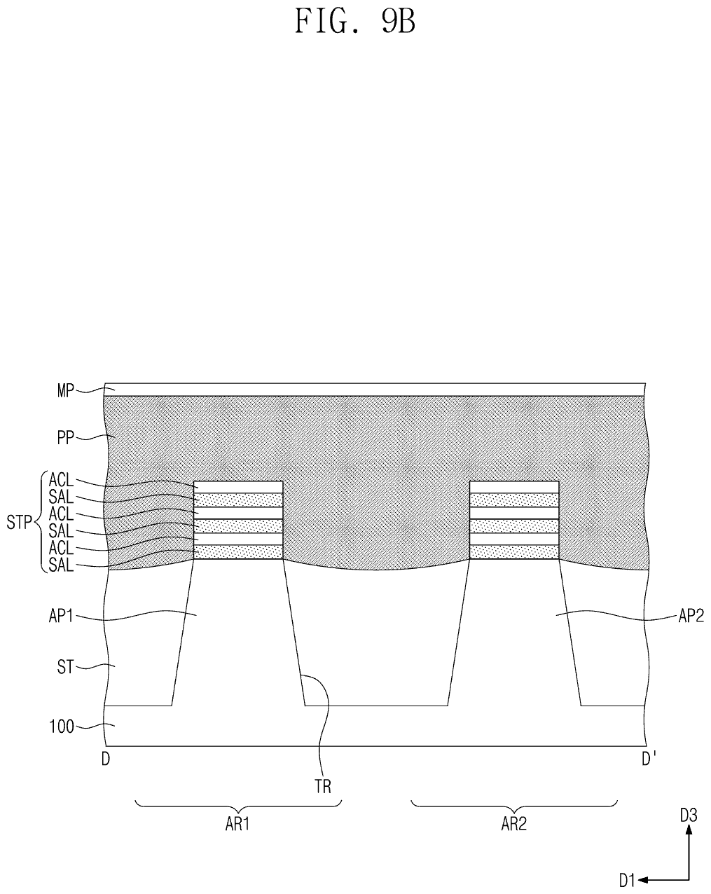

Referring to FIGS. 9A and 9B, sacrificial patterns PP may be formed on the substrate 100 to cross or intersect the stacking patterns STP. Each of the sacrificial patterns PP may be a line-shaped or bar-shaped pattern extending in the first direction D1. The sacrificial patterns PP may be spaced apart from each other in the second direction D2. The formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may include, for example, polysilicon.

A pair of the gate spacers GS may be formed on opposite side surfaces of each of the sacrificial patterns PP. The formation of the gate spacers GS may include forming a gate spacer layer on the substrate 100 to have a uniform thickness and anisotropically etching the gate spacer layer.

Referring to FIGS. 10A, 10B, and 10C, the first recesses RS1 may be formed in the stacking patterns STP on the first active pattern AP1. The second recesses RS2 may be formed in the stacking patterns STP on the second active pattern AP2. Thus, the device isolation layer ST may be further recessed.

In detail, the first recesses RS1 may be formed by an etching process using the hard mask patterns MP and the gate spacers GS as an etch mask. Each of the first recesses RS1 may be formed between a pair of the sacrificial patterns PP. A width of each of the first recesses RS1 in the second direction D2 may decrease as a distance to the substrate 100 decreases. Thus, the first to third semiconductor patterns SP1, SP2, and SP3 between adjacent ones of the first recesses RS1 may be formed from the active layers ACL of the stacking patterns STP. The first to third semiconductor patterns SP1, SP2, and SP3, which are sequentially stacked, may constitute the first channel patterns CH1.

The sacrificial layers SAL may be exposed by the first recesses RS1. A selective etching process may be performed on the sacrificial layers SAL exposed. The selective etching process may include a wet etching process, which is performed to selectively remove only silicon-germanium (SiGe). Each of the sacrificial layers SAL may be indented by the selective etching process. The inner spacers ISP may be formed to at least partially fill the indented regions of the sacrificial layers SAL.

The second recesses RS2 in the stacking pattern STP on the second active pattern AP2 may be formed by substantially the same or similar method as that for the first recesses RS1. The first to third semiconductor patterns SP1, SP2, and SP3 between adjacent ones of the second recesses RS2 may be formed from the active layers ACL of the stacking patterns STP, and the first to third semiconductor patterns SP1, SP2, and SP3 may constitute the second channel patterns CH2. The selective etching process may also be performed on the sacrificial layers SAL, which are exposed by the second recesses RS2, to form the indent regions IDE on the second active pattern AP2. Due to the indent regions IDE, the second recesses RS2 may have a wavy or nonlinear inner side surface. The inner spacers ISP may not be formed in the indent regions IDE on the second active pattern AP2.

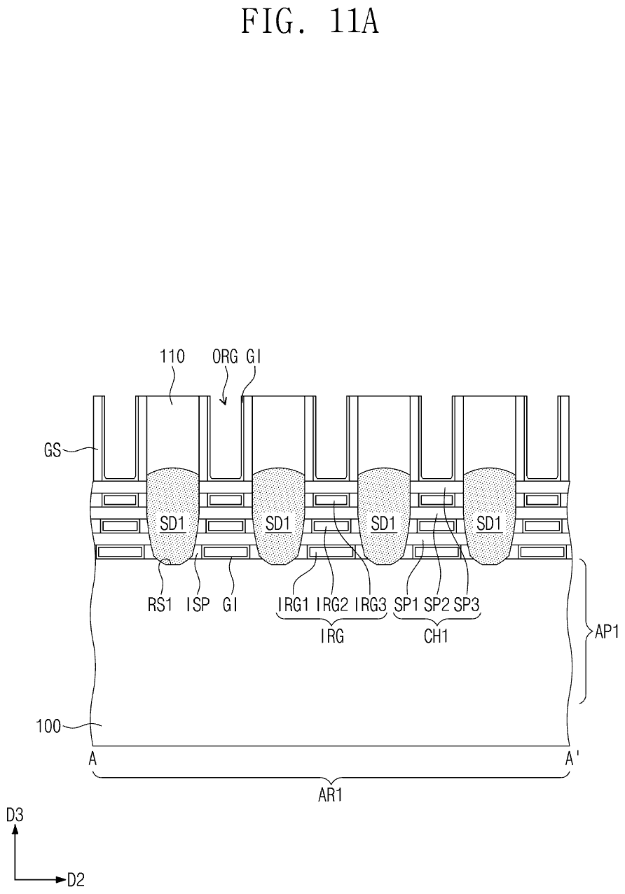

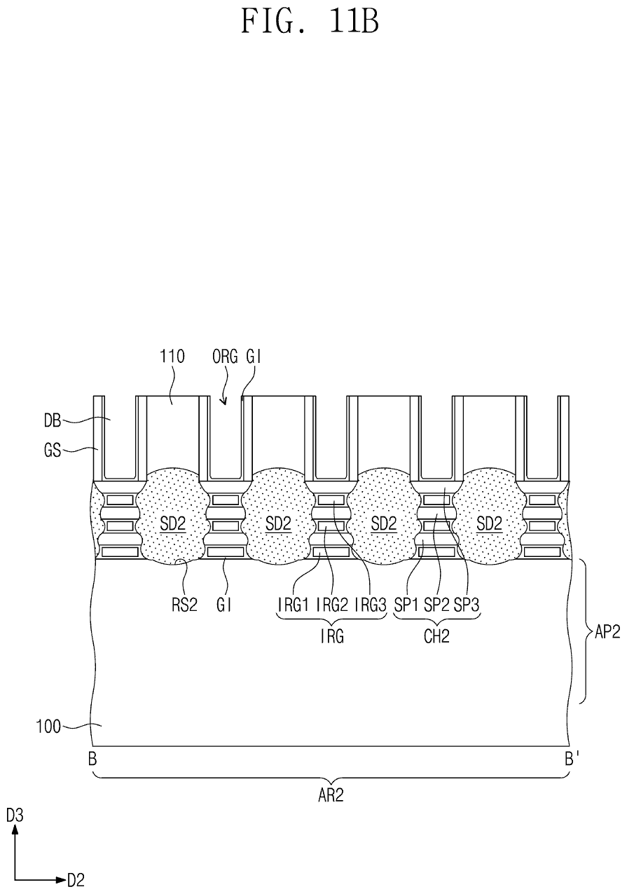

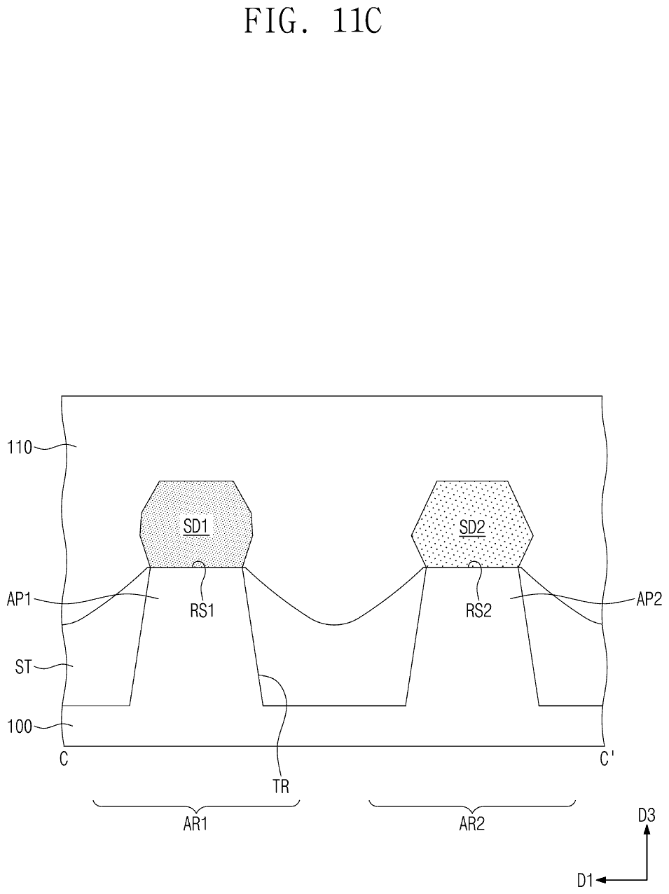

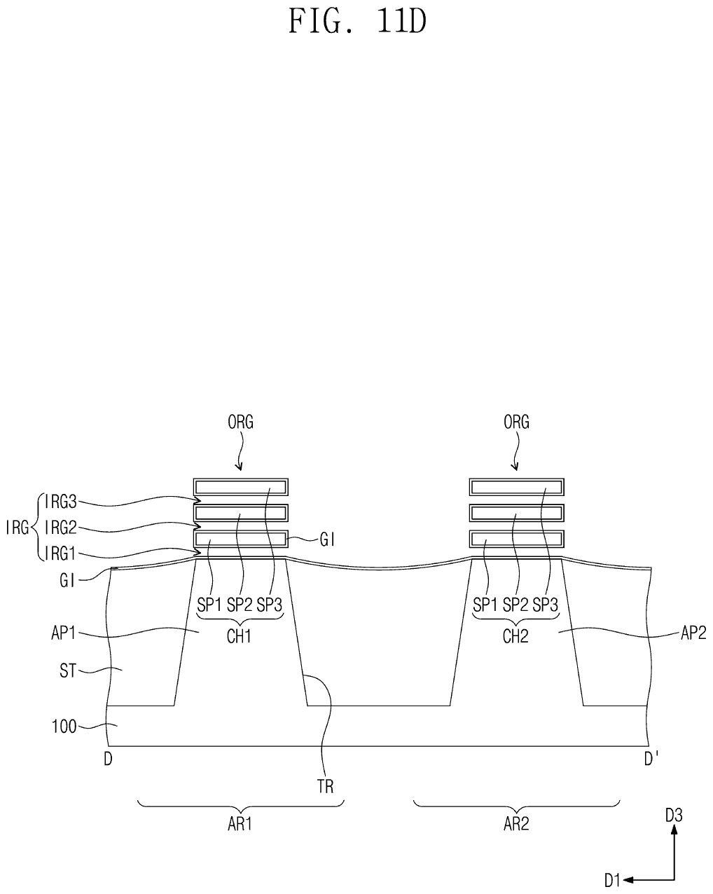

Referring to FIGS. 11A, 11B, 11C, and 11D, the first source/drain patterns SD1 may be formed in the first recesses RS1, respectively. The first source/drain patterns SD1 may be formed by a selective epitaxial growth (SEG) process using inner surfaces of the first recesses RS1 as a seed layer. The first source/drain patterns SD1 may be grown using the first to third semiconductor patterns SP1, SP2, and SP3 and the substrate 100, which are exposed by the first recesses RS1, as a seed layer. For example, the SEG process may include a chemical vapor deposition (CVD) process and/or a molecular beam epitaxy (MBE) process.

The first source/drain patterns SD1 may be formed of or include the same semiconductor element (e.g., Si) as the substrate 100. As an example, during the formation of the first source/drain patterns SD1, the first source/drain patterns SD1 may be doped in-situ with n-type impurities (e.g., phosphorus, arsenic, or antimony). As another example, impurities may be injected into the first source/drain patterns SD1, after the formation of the first source/drain patterns SD1.

The second source/drain patterns SD2 may be formed in the second recesses RS2, respectively. Similar to the first source/drain patterns SD1, the second source/drain patterns SD2 may be formed by a SEG process using the inner surfaces of the second recesses RS2 as a seed layer.

Unlike the first source/drain patterns SD1, the second source/drain patterns SD2 may be formed of or include a semiconductor material (e.g., SiGe) whose lattice constant is greater than that of a semiconductor material of the substrate 100. P-type impurities (e.g., boron, gallium, or indium) may be injected into the second source/drain patterns SD2.

Next, the first interlayer insulating layer 110 may be formed to cover or at least partially overlap the first and second source/drain patterns SD1 and SD2, the hard mask patterns MP, and the gate spacers GS. For example, the first interlayer insulating layer 110 may include silicon oxide. Thereafter, a planarization process may be performed on the first interlayer insulating layer 110 to expose top surfaces of the sacrificial patterns PP. In some embodiments, all of the hard mask patterns MP may be removed by the planarization process. As a result, the top surface of the first interlayer insulating layer 110 may be coplanar with the top surfaces of the sacrificial patterns SAP and the top surfaces of the gate spacers GS. The sacrificial patterns PP may be exposed to the outside.

In some embodiments, the exposed sacrificial patterns PP may be selectively removed. Since the sacrificial patterns PP are removed, an outer region ORG may be formed to expose the sacrificial layers SAL. The sacrificial layers SAL, which are exposed through the outer region ORG, may be selectively removed. Thus, first to third inner regions IRG1, IRG2, and IRG3 may be formed. As a result of the etching process of selectively removing the sacrificial layers SAL, the first to third semiconductor patterns SP1, SP2, and SP3 may be left, and only the sacrificial layers SAL may be removed. For example, the first inner region IRG1 may be formed between the first or second active patterns AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

The first to third semiconductor patterns SP1, SP2, and SP3 may be exposed by the first to third inner regions IRG1, IRG2, and IRG3 and the outer region ORG. The gate insulating layer GI may be formed on the exposed first to third semiconductor patterns SP1, SP2, and SP3. The gate insulating layer GI may be formed to enclose or at least partially surround each of the first to third semiconductor patterns SP1, SP2, and SP3. Thus, the gate insulating layer GI may be formed in the first to third inner regions IRG1, IRG2, and IRG3 and the outer region ORG.

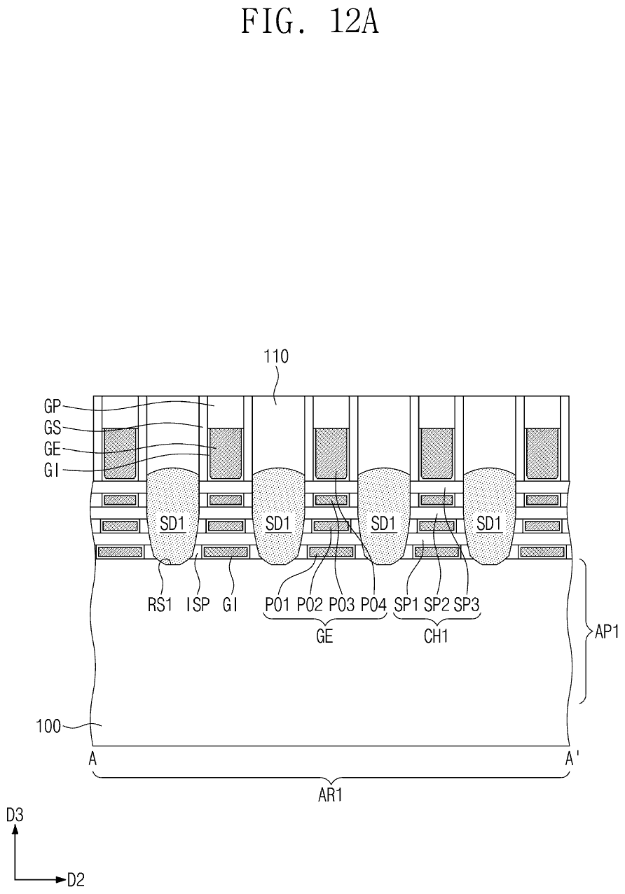

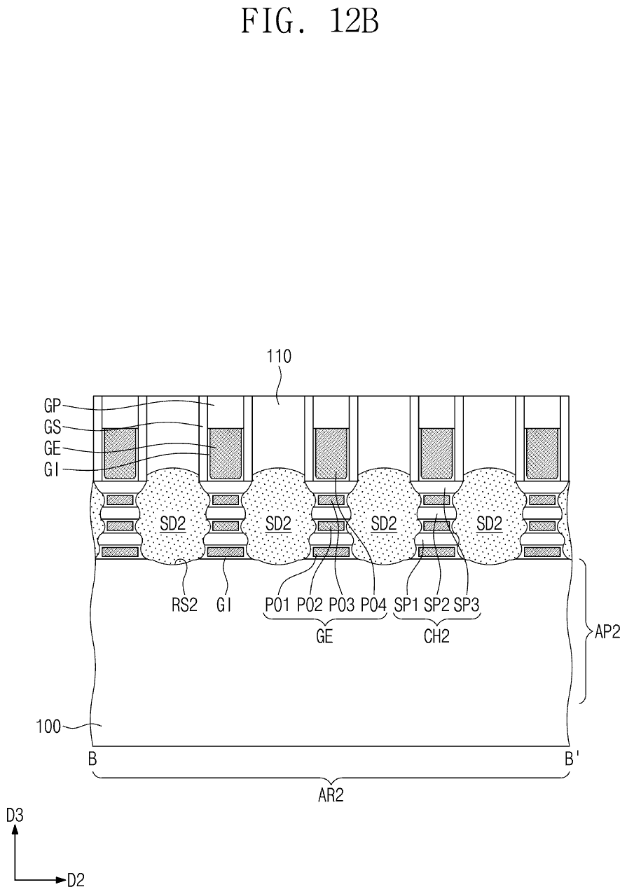

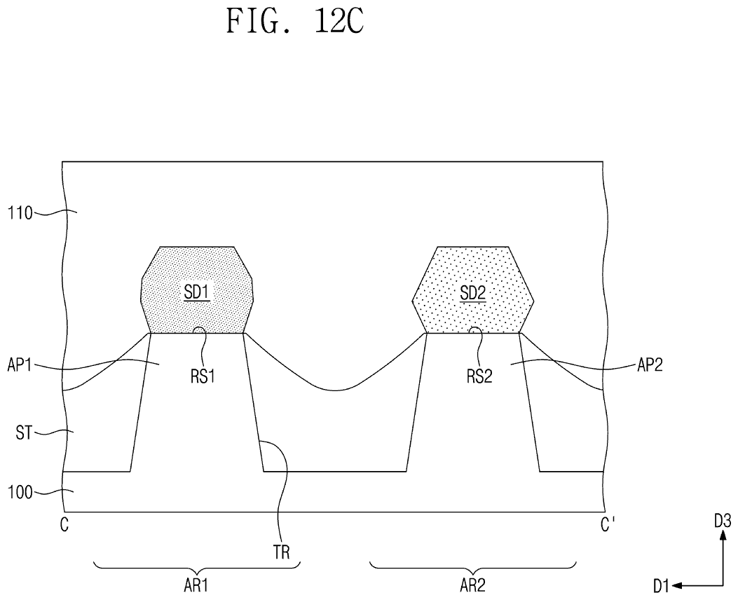

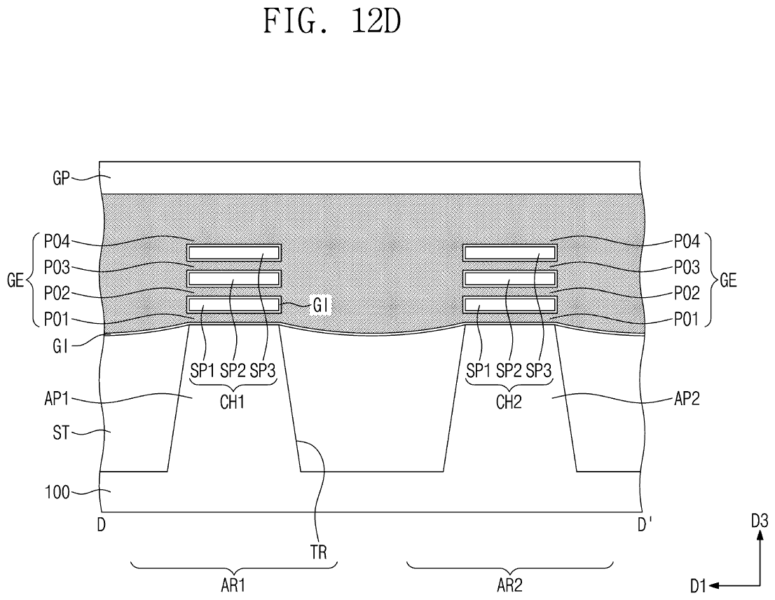

Referring to FIGS. 12A, 12B, 12C, and 12D, the gate electrodes GE may be formed on the gate insulating layer GI. Each of the gate electrodes GE may include the first to third inner electrodes PO1, PO2, and PO3 and the outer electrode PO4. For example, the first inner electrode PO1 may be formed in the first inner region IRG1, the second inner electrode PO2 may be formed in the second inner region IRG2, and the third inner electrode PO3 may be formed in the third inner region IRG3. The outer electrode PO4 may be formed in the outer region ORG. Thereafter, a planarization process may be performed on the gate electrodes GE.

The gate capping pattern GP may be formed on the gate electrodes GE. The gate capping pattern GP may cover or at least partially overlap the gate electrodes GE. The top surface of the gate capping pattern GP may be coplanar with the top surface of the first interlayer insulating layer 110.

Referring to FIGS. 13A, 13B, and 13C, the second interlayer insulating layer 120 may be formed on the first interlayer insulating layer 110. The second interlayer insulating layer 120 may cover or at least partially overlap the first interlayer insulating layer 110 and the gate capping pattern GP.

The first contact recesses CR1 may be formed on the first active region AR1 to penetrate or extend into the first and second interlayer insulating layers 110 and 120 and to extend into the first source/drain patterns SD1. The formation of the first contact recesses CR1 may include forming mask patterns on the second interlayer insulating layer 120, performing an anisotropic etching process using the mask patterns, and removing the mask patterns. Each of the first contact recesses CR1 may be located between a pair of the gate electrodes GE. For example, the anisotropic etching process may be performed until bottom surfaces of the first contact recesses CR1 are lower than the second semiconductor pattern SP2 of the first channel pattern CH1 relative to the bottom surface of the substrate 100 in the third direction D3.

Next, a first barrier layer BL1 may be formed on the substrate 100. The first barrier layer BL1 may cover the inner surfaces of the first contact recesses CR1 and the second interlayer insulating layer 120. The first barrier layer BL1 may be in contact with the first source/drain patterns SD1. The first barrier layer BL1 may have a uniform thickness (e.g., the first thickness T1).

The metal-semiconductor compound layers SC may be formed between the first barrier layer BL1 and the first source/drain patterns SD1 by a thermal treatment process on the first barrier layer BL1. A portion of the first barrier layer BL1 adjacent to the first source/drain patterns SD1 may be transformed to form the metal-semiconductor compound layers SC. Thus, the first barrier layer BL1 may have a relatively small thickness near the first source/drain patterns SD1, but the present disclosure is not limited to this example.

In some embodiments, the first barrier layer BL1 may be formed by a deposition process, which is performed at a high temperature of about 500° C. or higher. The first barrier layer BL1 and the metal-semiconductor compound layers SC may be formed at the same time. In this case, the thermal treatment process on the first barrier layer BL1 may be omitted.

A first seed layer SDL1 may be formed on the first barrier layer BL1. The first seed layer SDL1 may cover or at least partially overlap the first barrier layer BL1 with a uniform thickness. For example, the first seed layer SDL1 may have a smaller thickness than the first barrier layer BL1. The first seed layer SDL1 may be formed by a chemical vapor deposition (CVD) process and an atomic layer deposition (ALD) process.

In some embodiments, the first seed layer SDL1 may be formed by a deposition process using a WF₆ gas. The first seed layer SDL1 may include tungsten atoms and fluorine atoms. In this case, the fluorine atom may be present as a substitutional defect between the tungsten atoms. Since the size of the fluorine atom is smaller than that of the tungsten atom, a bonding length between the tungsten atoms may be increased, and thus, a tensile stress may be exerted on elements adjacent to the first seed layer SDL1. Accordingly, the tensile stress may be exerted on the first to third semiconductor patterns SP1, SP2, and SP3 of the first channel pattern CH1.

Next, a first lower metal layer LFL1 may be formed on the first barrier layer BL1. The first lower metal layer LFL1 may be grown using the first seed layer SDL1 as a seed layer. The first lower metal layer LFL1 may be formed by a chemical vapor deposition process. The first lower metal layer LFL1 may at least partially fill a remaining region of the first contact recesses CR1.

In some embodiments, the formation of the first lower metal layer LFL1 may include performing a nitrogen treatment process on the first seed layer SDL1. As a result of the nitrogen treatment process, the first lower metal layer LFL1 may be formed in the first contact recesses CR1. Thus, a void or a seam may not be formed in the first lower metal layer LFL1.

Referring to FIGS. 14A, 14B, and 14C, the second contact recesses CR2 may be formed on the second active region AR2 to penetrate or extend into the first and second interlayer insulating layers 110 and 120 and to extend into the second source/drain patterns SD2. The formation of the second contact recesses CR2 may be substantially the same as the formation of the first contact recesses CR1. Each of the second contact recesses CR2 may be located between a pair of the gate electrodes GE. For example, an anisotropic etching process may be performed until bottom surfaces of the second contact recesses CR2 are lower than the second semiconductor pattern SP2 of the second channel pattern CH2 relative to the bottom surface of the substrate 100 in the third direction D3.

Thereafter, a second barrier layer BL2 may be formed on the substrate 100 to have a uniform thickness. The second barrier layer BL2 may cover or at least partially overlap the inner surface of the second contact recesses CR2 and the second interlayer insulating layer 120. The second barrier layer BL2 may be in contact with the second source/drain patterns SD2. The second barrier layer BL2 may have substantially the same thickness (e.g., the first thickness T1) as the first barrier layer BL1, but the present disclosure is not limited to this example.

The metal-semiconductor compound layers SC may be formed between the second barrier layer BL2 and the second source/drain patterns SD2 by a thermal treatment process on the second barrier layer BL2. A portion of the second barrier layer BL2 adjacent to the second source/drain patterns SD2 may be transformed to form the metal-semiconductor compound layers SC. In this case, the second barrier layer BL2 may have a relatively small thickness near the second source/drain patterns SD2.

A second seed layer SDL2 may be formed on the second barrier layer BL2. The second seed layer SDL2 may cover the second barrier layer BL2. The second seed layer SDL2 may have a non-uniform thickness. For example, the thickness of the second seed layer SDL2 may be larger on the bottom surfaces of the second contact recesses CR2 than on the side surfaces of the second contact recesses CR2. In other words, the second seed layer SDL2 may have a thickness different from the first seed layer SDL1. The second seed layer SDL2 may be formed using a physical vapor deposition (PVD) process.

In some embodiments, the second seed layer SDL2 may be formed by a deposition process using an argon gas. The second seed layer SDL2 may include tungsten atoms and argon atoms. In this case, the argon atom may be present as an interstitial defect between the tungsten atoms. Due to the presence of the argon atom as the interstitial defect, a compressive stress may be exerted on elements adjacent to the second seed layer SDL2. Accordingly, the compressive stress may be exerted on the first to third semiconductor patterns SP1, SP2, and SP3 of the second channel pattern CH2.

Next, a second lower metal layer LFL2 may be formed on the second barrier layer BL2. The second lower metal layer LFL2 may be grown using the second seed layer SDL2 as a seed layer. The second lower metal layer LFL2 may be formed by a chemical vapor deposition process. The second lower metal layer LFL2 may at least partially fill the remaining portions of the second contact recesses CR2. In some embodiments, a void or a seam may be formed in the second lower metal layer LFL2, but the present disclosure is not limited to this example.

In some embodiments, the first and second contact recesses CR1 and CR2 may be formed at the same time, the first and second barrier layers BL1 and BL2 may be formed at the same time, and the first and second lower metal layers LFL1 and LFL2 may be formed at the same time. In this case, a tensile or compressive stress may be exerted on the first and second channel patterns CH1 and CH2. In other words, the same kind of stress may be exerted on the first and second channel patterns CH1 and CH2.

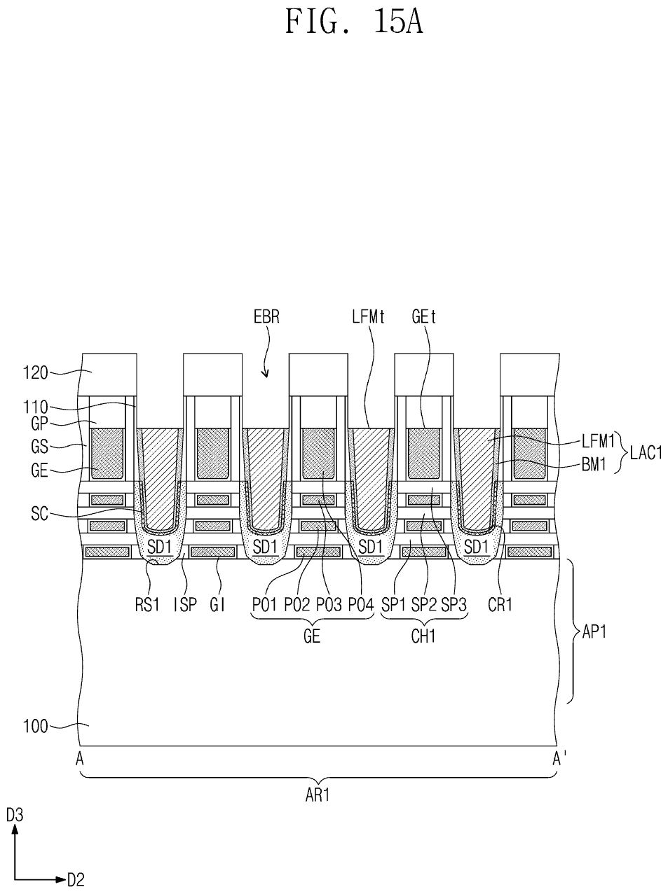

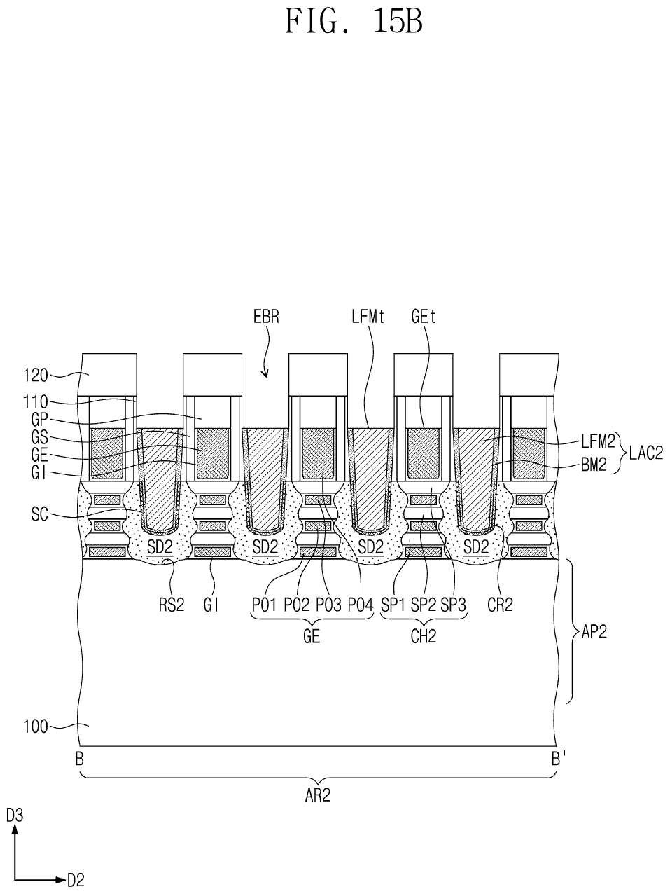

Referring to FIGS. 15A and 15B, a planarization process may be performed on the first and second lower metal layers LFL1 and LFL2. The planarization process may be performed to partially remove the first and second barrier layers BL1 and BL2 and the first and second lower metal layers LFL1 and LFL2. In some embodiments, the planarization process may be performed to expose the top surface of the second interlayer insulating layer 120.

Next, an etch-back process may be performed on the entire structure on the substrate 100. The etch-back process may be performed to selectively remove the first and second barrier layers BL1 and BL2 and the first and second lower metal layers LFL1 and LFL2. The first and second interlayer insulating layers 110 and 120 may not be removed by the etch-back process. As a result of the etch-back process, upper portions of the first and second barrier layers BL1 and BL2 and the first and second lower metal layers LFL1 and LFL2 may be removed to form etch-back regions EBR.

As a result, the first and second barrier patterns BM1 and BM2 may be formed from the first and second barrier layers BL1 and BL2, respectively, and the first and second lower metal patterns LFM1 and LFM2 may be formed from the first and second lower metal layers LFL1 and LFL2, respectively. Accordingly, the first lower active contacts LAC1 including the first barrier pattern BM1 and the first lower metal pattern LFM1 may be formed, and the second lower active contacts LAC2 including the second barrier pattern BM2 and the second lower metal pattern LFM2 may be formed. For example, the etch-back process may be performed until top surfaces LFMt of the first and second lower metal patterns LFM1 and LFM2 are substantially coplanar with top surfaces GEt of the gate electrodes GE.

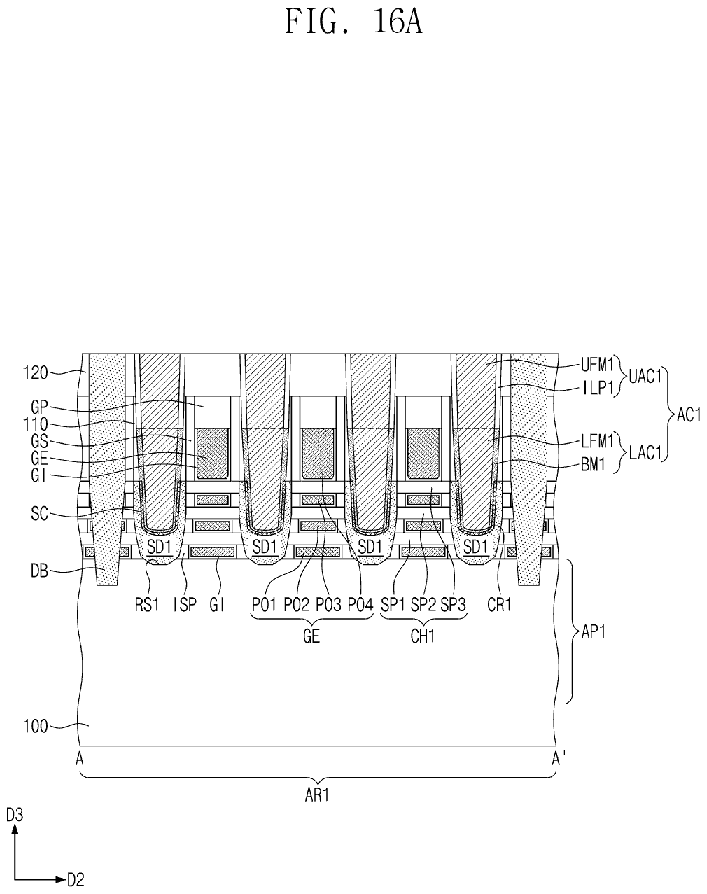

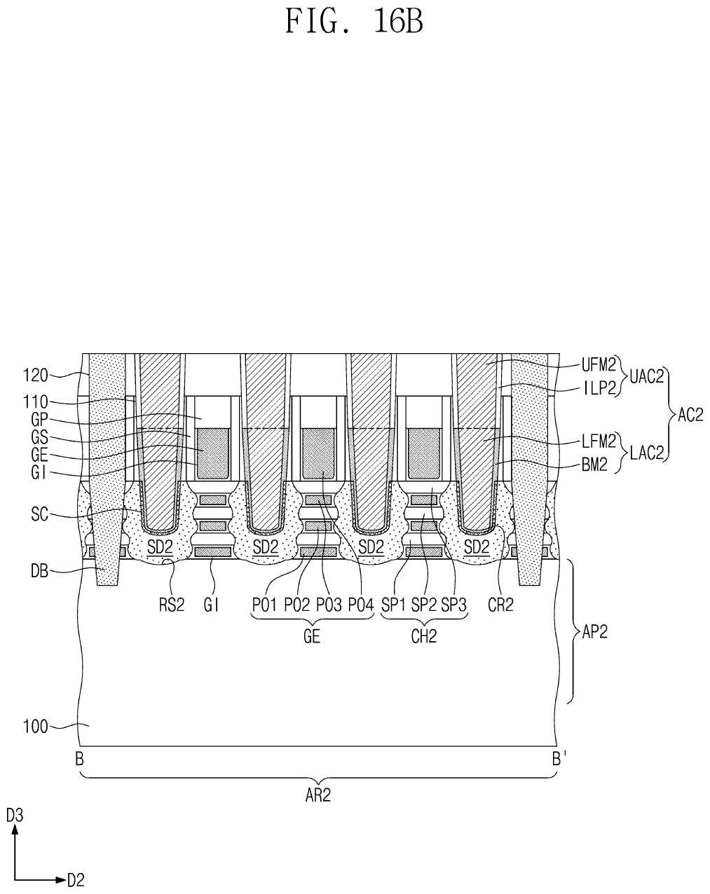

Referring to FIGS. 16A and 16B, the first and second upper active contacts UAC1 and UAC2 may be formed in the etch-back regions EBR. The first upper active contacts UAC1 may be placed on the first lower active contacts LAC1, respectively. The second upper active contacts UAC2 may be placed on the second lower active contacts LAC2, respectively. In some embodiments, the first and second upper active contacts UAC1 and UAC2 may be formed at the same time. The formation of the first and second upper active contacts UAC1 and UAC2 may include forming an insulating layer on the substrate 100, performing an anisotropic etching process on the insulating layer, forming an upper metal layer to at least partially fill the etch-back regions EBR, and performing a planarization process on the upper metal layer.

The insulating layer may be formed to cover or at least partially overlap the etch-back regions EBR with a uniform thickness. The insulating layer may cover or at least partially overlap the top surfaces LFMt of the first and second lower metal patterns LFM1 and LFM2. The anisotropic etching process may be performed to remove a portion of the insulating layer, and in this case, the top surfaces of the first and second barrier patterns BM1 and BM2 may be covered with or overlapped by a remaining portion of the insulating layer, and the top surfaces of the first and second lower metal patterns LFM1 and LFM2 may be re-exposed to the outside. Accordingly, the insulating layer may be placed on only side surfaces of the etch-back regions EBR. As a result, the first and second insulating patterns ILP1 and ILP2 may be formed from the insulating layer. The upper metal layer may be formed to cover or at least partially overlap the top surface of the second interlayer insulating layer 120. The planarization process may be performed to remove a portion of the upper metal layer and to re-open the top surface of the second interlayer insulating layer 120. The first and second upper metal patterns UFM1 and UFM2 may be formed from the upper metal layer.

In some embodiments, the upper metal layer may be grown using the exposed top surfaces LFMt of the first and second lower metal patterns LFM1 and LFM2 as a seed layer. In other words, the upper metal layer may be formed by a selective growth process. Thus, interfaces between the first and second lower metal patterns LFM1 and LFM2 and the first and second upper metal patterns UFM1 and UFM2 may not be visible or observable, and a contact resistance between the first and second lower metal patterns LFM1 and LFM2 and the first and second upper metal patterns UFM1 and UFM2 may be low.

Thereafter, the division structures DB may be formed. The division structures DB may be formed to penetrate or extend into the first and second interlayer insulating layers 110 and 120 and to extend into upper portions of the first and second active patterns AP1 and AP2. The division structures DB may include an insulating material (e.g., silicon oxide or silicon nitride).

Referring back to FIGS. 5A, 5B, 5C, and 5D, the gate contacts GC may be formed to penetrate or extend into the second interlayer insulating layer 120 and the gate capping pattern GP and may be connected to the gate electrodes GE.

The third interlayer insulating layer 130 may be formed on the second interlayer insulating layer 120. The third interlayer insulating layer 130 may cover or at least partially overlap the top surface of the second interlayer insulating layer 120. The first metal layer M1 including the first vias VI1, the first power line M1_R1, the second power line M1_R2, and the first interconnection lines M1_I may be formed in the third interlayer insulating layer 130. The fourth interlayer insulating layer 140 may be formed on the third interlayer insulating layer 130. The second metal layer M2 including the second interconnection lines M2_I may be formed in the fourth interlayer insulating layer 140.

In a semiconductor device according to some embodiments of the present disclosure, an active contact may be configured to exert a stress on channel patterns. In this case, a carrier mobility of the channel patterns may be increased. In addition, a lower metal pattern constituting a lower active contact may be in contact with an upper metal pattern constituting an upper active contact. Thus, a contact resistance between the lower and upper active contacts may be lowered. Furthermore, an insulating pattern constituting the upper active contact may have a thickness that is substantially equal to or larger than that of a barrier pattern constituting the lower active contact. Accordingly, the upper metal pattern may be easily formed from the lower metal pattern. Thus, the electrical characteristics of the semiconductor device may be improved.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor device, comprising:
a channel pattern on a substrate;
a source/drain pattern electrically connected to the channel pattern;
a gate electrode on the channel pattern;
an interlayer insulating layer on the source/drain pattern; and
an active contact that extends into the interlayer insulating layer and is electrically connected to the source/drain pattern,
wherein the active contact comprises:
a lower active contact that comprises a barrier pattern and a lower metal pattern on the barrier pattern; and
an upper active contact on the lower active contact, wherein the upper active contact comprises an upper metal pattern and an insulating pattern on side surfaces of the upper metal pattern, and
wherein the lower metal pattern and the upper metal pattern are in contact with each other.

2. The semiconductor device of claim 1, wherein the lower active contact extends into a portion of the source/drain pattern.

3. The semiconductor device of claim 1, wherein the lower metal pattern and the upper metal pattern comprise a same metal material.

4. The semiconductor device of claim 1, wherein a thickness of the barrier pattern in a first direction that is parallel to a bottom surface of the substrate is substantially equal to a thickness of the insulating pattern in the first direction.

5. The semiconductor device of claim 1, wherein a thickness of the barrier pattern in a first direction that is parallel to a bottom surface of the substrate is smaller than a thickness of the insulating pattern in the first direction.

6. The semiconductor device of claim 1, wherein a width of a top portion of the lower metal pattern in a first direction that is parallel to a bottom surface of the substrate is substantially equal to a width of a bottom portion of the upper metal pattern in the first direction.

7. The semiconductor device of claim 1, wherein a width of a top portion of the lower metal pattern in a first direction that is parallel to a bottom surface of the substrate is larger than a width of a bottom portion of the upper metal pattern in the first direction.

8. The semiconductor device of claim 1, wherein a top surface of the lower metal pattern is coplanar with a top surface of the gate electrode.

9. The semiconductor device of claim 1, further comprising a metal-semiconductor compound layer between the lower active contact and the source/drain pattern.

10. The semiconductor device of claim 1, wherein the channel pattern comprises:
a first semiconductor pattern, a second semiconductor pattern, and a third semiconductor pattern that are spaced apart from each other, and
a bottom end of the lower active contact is located at a level lower less than the second semiconductor pattern.

11. A semiconductor device, comprising:
a substrate that comprises a first active region and a second active region;
a first channel pattern on the first active region and a second channel pattern on the second active region;
a first source/drain pattern electrically connected to the first channel pattern;
a second source/drain pattern electrically connected to the second channel pattern;
a gate electrode on the first channel pattern and the second channel pattern;
a first active contact that extends into a portion of the first source/drain pattern; and
a second active contact that extends into a portion of the second source/drain pattern,
wherein the first active contact is configured to exert a tensile stress on the first channel pattern, and
wherein the second active contact is configured to exert a compressive stress on the second channel pattern.

12. The semiconductor device of claim 11, wherein each of the first active contact and the second active contact comprises a lower active contact and an upper active contact on the lower active contact.

13. The semiconductor device of claim 12, wherein:
the lower active contact comprises a barrier pattern and a lower metal pattern on the barrier pattern,
the upper active contact comprises an upper metal pattern and an insulating pattern on side surfaces of the upper metal pattern, and
the lower metal pattern and the upper metal pattern are in contact with each other.

14. The semiconductor device of claim 11, wherein:
each of the first channel pattern and the second channel pattern comprises a plurality of semiconductor patterns spaced apart from each other, and
the first active region and the second active region have different conductivity types from each other.

15. A method of fabricating a semiconductor device, comprising:
providing a substrate that comprises a first active region and a second active region;
forming a first channel pattern and a first source/drain pattern that are electrically connected to each other and are on the first active region;
forming a second channel pattern and a second source/drain pattern that are electrically connected to each other and are on the second active region;
forming a first seed layer in a first contact recess that extends into a portion of the first source/drain pattern; and
forming a second seed layer in a second contact recess that extends into a portion of the second source/drain pattern,
wherein the first seed layer is configured to exert a stress on the first channel pattern, and
wherein the second seed layer is configured to exert a stress on the second channel pattern.

16. The method of claim 15, wherein:
the first seed layer is formed by a chemical vapor deposition process or an atomic layer deposition process, and
the second seed layer is formed by a physical vapor deposition process.

17. The method of claim 15, wherein:
the first seed layer has a uniform thickness on a bottom surface of the first contact recess and a side surface of the first contact recess, and
the second seed layer is thicker on a bottom surface of the second contact recess than on a side surface of the second contact recess.

18. The method of claim 15, further comprising:
forming a first lower metal pattern in the first contact recess; and
forming a second lower metal pattern in the second contact recess.

19. The method of claim 18, wherein the forming of the first lower metal pattern comprises performing a nitrogen treatment process on the first seed layer.

20. The method of claim 18, further comprising:
forming a first upper active contact on the first lower metal pattern; and
forming a second upper active contact on the second lower metal pattern,
wherein the first upper active contact comprises a first upper metal pattern in contact with the first lower metal pattern, and
the second upper active contact comprises a second upper metal pattern in contact with the second lower metal pattern.
